(19) United States
(12) Patent Application Publication
(10) Pub. No.: US 2025/0141412 A1
(43) Pub. Date: May 1, 2025

(54) METHODS AND APPARATUS TO MODULATE SIGNALS USING MULTI-CLASS MODULATION CIRCUITRY

(71) Applicant: Texas Instruments Incorporated, Dallas, TX (US)

(72) Inventors: Jianquan Liao, Shanghai (CN); Zejian Wang, Shanghai (CN); Pourya Assem, Dallas, TX (US); Kannan Krishna, Dallas, TX (US); Zhenzhen Chen, Shanghai (CN); Jing Xu, Shanghai (CN); Shurong Xia, Plano, TX (US); Chi Cheong, Frisco, TX (US)

(21) Appl. No.: 18/385,848

(22) Filed: Oct. 31, 2023

(51) Int. Cl. H03F 3/217; H03F 3/21

(52) U.S. Cl. CPC H03F 3/217; H03F 3/211; H03F 2200/171

(57) ABSTRACT

An example apparatus includes: class D amplifier circuitry having a first input, a second input, a third input, and an output, the first input of the class D amplifier circuitry coupled to the output of the class D amplifier circuitry; and class AB amplifier circuitry having a first input, a second input, a third input, and an output, the first input of the class AB amplifier circuitry coupled to the first input of the class D amplifier circuitry and the output of the class D amplifier circuitry, the second and third inputs of the class AB amplifier circuitry coupled to the second and third inputs of the class D amplifier circuitry, and the output of the class AB amplifier circuitry.

### CROSS REFERENCE TO RELATED APPLICATIONS

The present application is related to U.S. patent application Ser. No. 18/476,825, titled “POWER-ON AND SHUT DOWN POP REDUCTION IN AUDIO SYSTEMS,” Attorney Docket Number T102989US01, filed on Sep. 28, 2023, of which is hereby incorporated herein by reference in its entirety.

### TECHNICAL FIELD

This description relates generally to modulation circuitry and, more particularly, to methods and apparatus to modulate a signal using multi-class modulation circuitry.

### BACKGROUND

Electronic systems utilize amplifier circuitry for a wide range of operations. One example use for amplifier circuitry is signal modulation. In modulation circuitry, amplifier circuitry generates switching signals to control power stage circuitry which modulates an input signal for supply to a load. By controlling the power stage circuitry, the amplifier circuitry generates relatively high-power modulated signals based on relatively low power input signals. Such modulation circuitry allows electronic systems to generate relatively complex signals from relatively less complex signals.

### SUMMARY

For methods and apparatus to modulate a signal using multi-class modulation circuitry, an example apparatus includes class D amplifier circuitry having a first input, a second input, a third input, and an output, the first input of the class D amplifier circuitry coupled to the output of the class D amplifier circuitry; and class AB amplifier circuitry having a first input, a second input, a third input, and an output, the first input of the class AB amplifier circuitry coupled to the first input of the class D amplifier circuitry and the output of the class D amplifier circuitry, the second and third inputs of the class AB amplifier circuitry coupled to the second and third inputs of the class D amplifier circuitry, and the output of the class AB amplifier circuitry.

### BRIEF DESCRIPTION OF THE DRAWINGS

FIG. 1 is a block diagram of an example audio system including example multi-class modulation circuitry that implements a one inductor (1L) modulation technique to generate a modulated signal.

FIG. 2 is a block diagram of an example of the multi-class modulation circuitry of FIG. 1 including example class D amplifier circuitry and example class AB amplifier circuitry.

FIGS. 3A and 3B are a schematic diagram of an example of the class D amplifier circuitry of FIG. 2 including example feedforward circuitry.

FIG. 4 is a schematic diagram of an example of the class AB amplifier circuitry of FIG. 2.

FIG. 5 is a schematic diagram of an example input stage that when coupled to the multi-class modulation circuitry of FIGS. 1 and 2 converts digital audio signals to analog audio signals.

FIG. 6 is a timing diagram of an example operation of the multi-class modulation circuitry of FIGS. 1 and 2 to implement 1L modulation.

FIG. 7 is a plot of an example pulse width modulation (PWM) of the class D amplifier circuitry of FIGS. 2, 3A, and 3B.

FIG. 8 is a plot of an example total harmonic distortion (THD) of the multi-class modulation circuitry of FIGS. 1 and 2 across a plurality of frequencies.

FIG. 9 is a plot of an example THD of the multi-class modulation circuitry of FIGS. 1 and 2 across a plurality of power values.

FIG. 10 is a plot of an example THD of the multi-class modulation circuitry of FIGS. 1 and 2 across a plurality of power values with and without the feedforward circuitry of FIG. 3B.

FIGS. 11A and 11B form a flowchart representative of example operations that may be performed to implement 1L modulation and/or more generally the multi-class modulation circuitry of FIGS. 1 and 2.

The same reference numbers or other reference designators are used in the drawings to designate the same or similar (functionally and/or structurally) features.

### DETAILED DESCRIPTION

The drawings are not necessarily to scale. Generally, the same reference numbers in the drawing(s) and this description refer to the same or like parts. Although the drawings show regions with clean lines and boundaries, some, or all of these lines and/or boundaries may be idealized. In reality, the boundaries and/or lines may be unobservable, blended and/or irregular.

Electronic systems utilize amplifier circuitry for a wide range of operations. One example use for amplifier circuitry is signal modulation. Signal modulation is a process or plurality of operations, to transform one or more signals to one or more modulated signals. The one or more modulated signals are modulated to represent the original one or more signals. Modulator circuitry may precondition signals to traverse different environments and/or be supplied to specific loads. In some examples, modulation circuitry uses a plurality of signal generation techniques to generate modulated signals which represent the original signals. Some modulation circuitry uses amplifier circuitry to generate switching signals which control power stage circuitry. The power stage circuitry generates modulated signals based on the switching signals. The modulated signals may be supplied to a load. By controlling the power stage circuitry, the amplifier circuitry generates relatively high-power modulated signals based on relatively low power input signals. Such modulation circuitry allows electronic systems to generate relatively complex signals from relatively less complex signals.

One instance of modulation circuitry utilizes class AB amplifier circuitry to supply a signal to a load. Class AB amplifier circuitry utilizes a sinusoidal waveform to control transistors of power stage circuitry. In some class AB amplifier circuitry, positive amplitudes drive a first transistor while negative amplitudes drive a second transistor. The first and second transistors generate the output of the class AB amplifier circuitry at a shared terminal. In such examples, the output of the class AB amplifier circuitry is an amplified version of the input signal. The output of the class AB amplifier circuitry is a linear output. Such linear outputs have a relatively high electromagnetic interference (EMI) immunity and may drive a load without inductor capacitor (LC) filter circuitry. However, driving the transistors of the class AB amplifier circuitry to generate a linear output has a relatively low power efficiency compared to alternative methods of modulation.

Another instance of modulation circuitry utilizes class D amplifier circuitry to supply a signal to a load. Class D amplifier circuitry utilizes a square waveform to control transistors of power stage circuitry. The class D amplifier circuitry generates the square waveform by comparing a sinusoidal waveform to a triangular waveform. Such a comparison may be referred to as pulse width modulation (PWM). The class D amplifier circuitry varies the duty cycle of the square waveform based on amplitudes to the sinusoidal waveform. The square waveform has a first logic state (e.g., logical one, logic high, logical zero, logic low) to enable a first transistor and a second logic state to enable a second transistor. The first and second transistors generate the output of the class D amplifier circuitry at a shared terminal. LC filter circuitry averages the output of the class D amplifier circuitry to construct the sinusoidal waveform. Class D amplifier circuitry has a relatively high efficiency compared to the class AB amplifier circuitry responsive to driving the transistors using logic states. However, the square waveform output of the class D amplifier circuitry needs bulky LC filter circuitry and is more susceptible to EMI.

In some implementations, such as audio devices, a plurality of amplifier circuitries are used to differentially drive a load. In some examples, an audio device may include two instances of class AB amplifier circuitry to supply a differential audio signal to a speaker. In such examples, both instances of the class AB amplifier circuitry drive a plurality of transistors in linear modes of operation. Increasing the number of transistors being driven in linear modes of operation decreases the power efficiency of the device. In another example, an audio device may include two instances of class D amplifier circuitry to supply a differential audio signal to a speaker. In such examples, each instance of the class D amplifier circuitry needs an inductor to filter the square waveform outputs. Such a need for a plurality of inductors increases a system on chip (SoC) size of the circuitry.

Examples described herein include methods and apparatus to modulate a signal using multi-class modulation circuitry. In some described examples, multi-class modulation circuitry implements a single inductor (1L) modulation technique. 1L modulation utilizes first amplifier circuitry and second amplifier circuitry to generate an asymmetric differential output. The first amplifier circuitry is class D amplifier circuitry generates a square waveform, as a first output, by modulating differential input signals. The class D amplifier circuitry generates the first output using multi-order modulator circuitry to generate an error signal. The second amplifier circuitry is class AB amplifier circuitry linearly generates a second output by modulating the differential input signals. In some described examples, the class AB amplifier circuitry has a relatively high gain which saturates the second output signal. In such examples, the second signal is non-linear and resembles a square waveform responsive to the class AB amplifier circuitry operating in a saturation mode of operation. In a saturation mode of operation, the class AB amplifier circuitry clips the second output signal to supply voltages. The output of the class AB amplifier circuitry is non-linear responsive to such clipping. However, the class AB amplifier circuitry operates in a linear mode of operation for relatively small voltages that occur during transitions between saturated states.

The class D amplifier circuitry includes feedforward circuitry to account for such non-ideal linearity of the second output of the class AB amplifier circuitry. In some described examples, the class D amplifier circuitry combines the second output with the error signal to compensate the first output for the linear operations of the class AB amplifier circuitry. The class D amplifier circuitry compares the combined signal to a triangular waveform to generate a square waveform having a varying duty cycle. Advantageously, the multi-class modulation circuitry reduces a total package size by using a single inductor. Advantageously, class AB amplifier circuitry reduces the need for bulky filter circuitry on one output of the multi-class modulation circuitry.

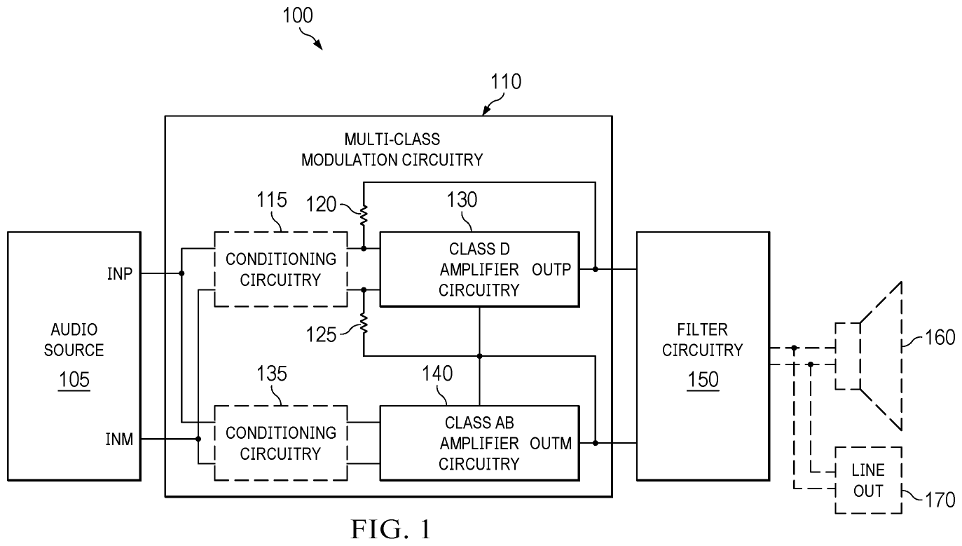

FIG. 1 is a block diagram of an example audio system 100. In the example of FIG. 1, the audio system 100 includes an example audio source 105, example multi-class modulation circuitry 110, first example conditioning circuitry 115, a first example resistor 120, a second example resistor 125, example class D amplifier circuitry 130, second example conditioning circuitry 135, example class AB amplifier circuitry 140, example filter circuitry 150, an example speaker 160, and an example line out 170. In some examples, such as when the filter circuitry 150 is coupled to the speaker 160, the audio system 100 produces an audible noise responsive to an audio signal from the audio source 105. In other examples, such as when the filter circuitry 150 is coupled to the line out 170, the audio system 100 supplies the audio signal to an external device to produce an audible noise. In such examples, the line out 170 may be an auxiliary (AUX) connector, driver circuitry, alternative audio connector, communication link, etc.

The audio source 105 is coupled to the amplifier circuitries 130, 140 by the conditioning circuitries 115, 135. The audio source 105 supplies a differential pair of input signals to the conditioning circuitries 115, 135. In the example of FIG. 1, the differential pair of input signals represent an audio signal that generates an audible sound when supplied to the speaker 160. The differential pair of input signals includes a plus input signal (INP) and a minus input signal (INM). In some examples, the difference between the plus input signal and the minus input signal represents the audio signal. In such examples, the audio source 105 amplifies the audio signal by a gain of one half to generate the plus input signal and inverts the plus input signal to generate the minus input signal. Although in the example of FIG. 1, the audio source 105 is illustrated, in some examples the audio source 105 may be external circuitry supplies the differential input signal.

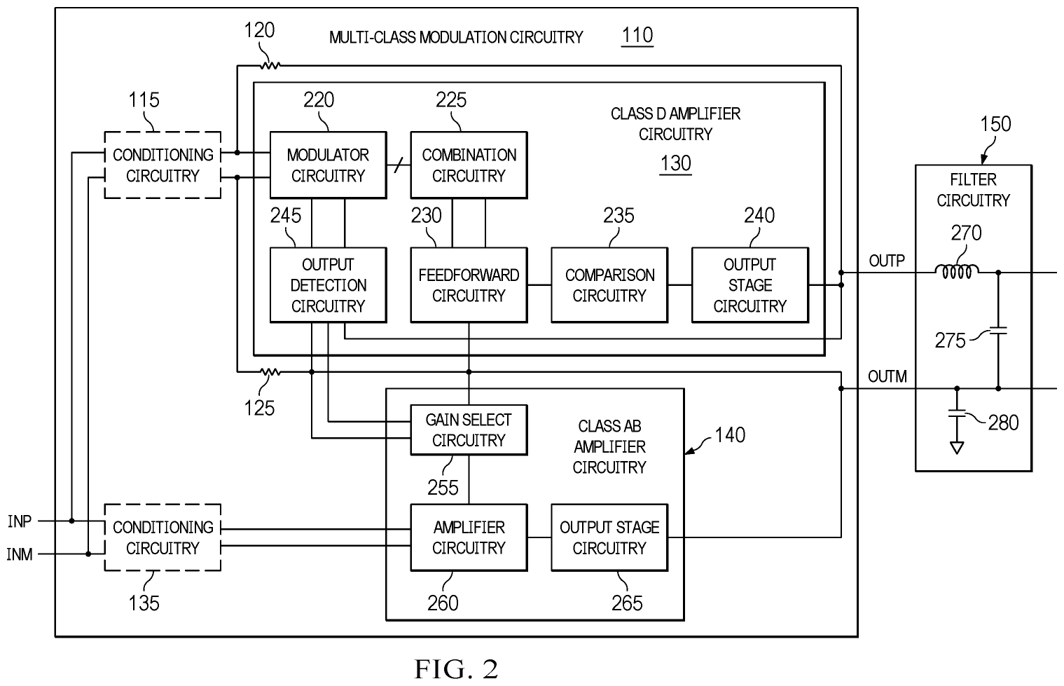

The multi-class modulation circuitry 110 is coupled to the audio source 105 and the filter circuitry 150. In the example of FIG. 1, the multi-class modulation circuitry 110 includes the conditioning circuitries 115, 135, the resistors 120, 125, the class D amplifier circuitry 130, and the class AB amplifier circuitry 140. The multi-class modulation circuitry 110 modulates the differential pair of input signals from the audio source 105 using 1 L modulation. The multi-class modulation circuitry 110 supplies a differential pair of output signals to the filter circuitry 150. The differential pair of output signals having a plus output signal (OUTP) and a minus output signal (OUTM). The plus output signal is an output of the class D amplifier circuitry 130 while the minus output signal is an output of the class AB amplifier circuitry 140. An example of the multi-class modulation circuitry 110 is illustrated in FIG. 2.

The first conditioning circuitry 115 has first and second terminals coupled to the audio source 105 and the second conditioning circuitry 135. The first conditioning circuitry 115 has third and fourth terminals coupled to the resistors 120, 125 and the class D amplifier circuitry 130. The first conditioning circuitry 115 receives the differential pair of input signals at the first and second terminals. The first conditioning circuitry 115 filters the differential pair of input signals. In some examples, the first conditioning circuitry 115 is filter circuitry that removes signals of frequencies outside of a range of pass-through frequencies. In such examples, the first conditioning circuitry 115 may be one or more instances of low pass filter circuitry, band-pass filter circuitry, etc. The first conditioning circuitry 115 supplies the differential pair of input signals to the class D amplifier circuitry 130.

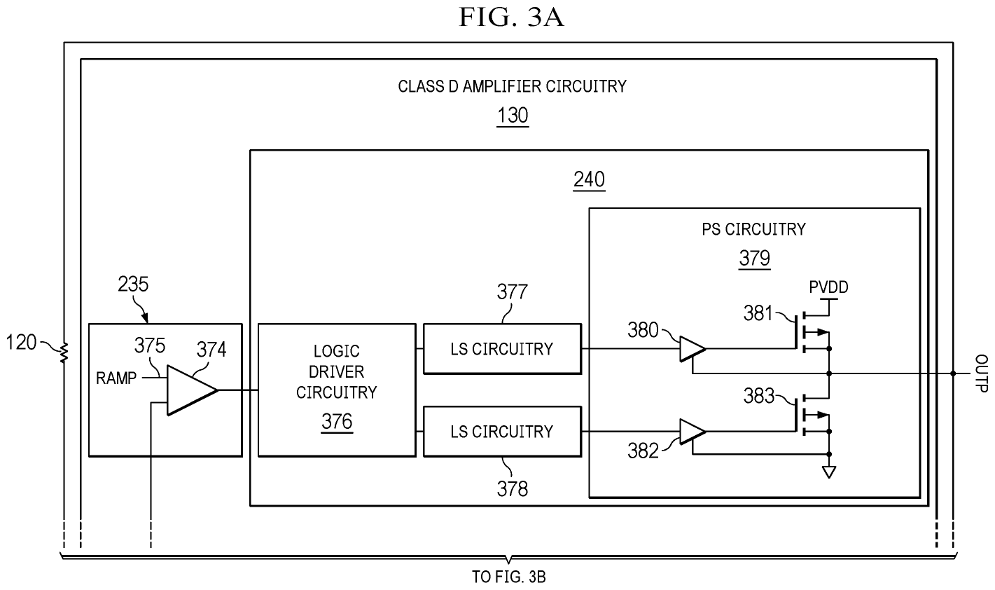

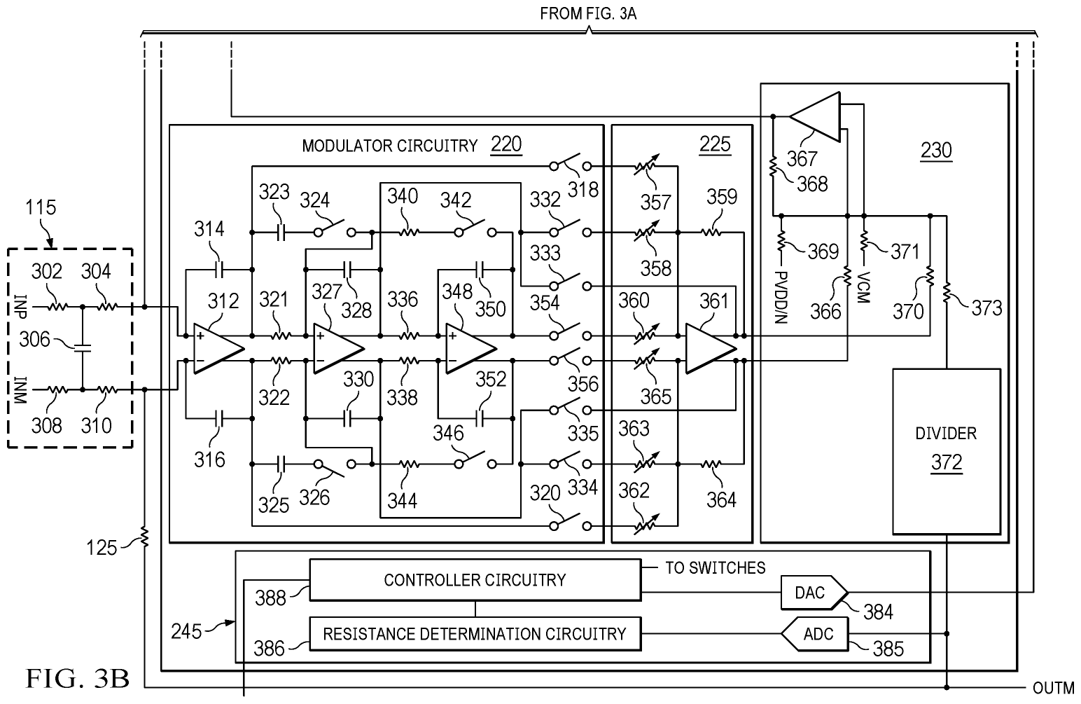

The first conditioning circuitry 115 receives the differential pair of output signals of the amplifier circuitries 130, 140. Components of the first conditioning circuitry 115 (illustrated in FIG. 3 and described below) combine the filtered input signals and the differential pair of output signals. The first conditioning circuitry 115 supplies the combined signals to the class D amplifier circuitry 130. In some examples, the combination of signals by components of the first conditioning circuitry 115 may be internal to class D amplifier circuitry 130. In the example of FIG. 1, the first conditioning circuitry 115 is illustrated. However, the multi-class modulation circuitry 110 may be modified to remove and/or include alternative circuitry in place of the first conditioning circuitry 115. For example, the first conditioning circuitry 115 may be illustrated as filter circuitry, replaced with summing resistors, and/or removed all together.

The first resistor 120 has a first terminal coupled to the first conditioning circuitry 115 and the class D amplifier circuitry 130 and a second terminal coupled to the class D amplifier circuitry 130 and the filter circuitry 150. The first resistor 120 couples the input of the class D amplifier circuitry 130 to the plus output signal. The first resistor 120 stabilizes timing of the loop formed between the input and output of the class D amplifier circuitry 130. In some examples, the first resistor 120 may be described and/or referred to as a feedback resistor.

The second resistor 125 has a first terminal coupled to the first conditioning circuitry 115 and the class D amplifier circuitry 130 and a second terminal coupled to the amplifier circuitries 130, 140, and the filter circuitry 150. The second resistor 125 couples the output of the class AB amplifier circuitry 140 to inputs of the amplifier circuitries 130, 140. The second resistor 125 stabilizes timing of the loop formed between the input and output of the class AB amplifier circuitry 140. In some examples, the second resistor 125 may be described and/or referred to as a feedback resistor.

In some examples, one or both of the resistors 120, 125 may be variable resistors. In such examples, resistances of the resistors 120, 125 are adjusted to be approximately equal. For example, the resistances of the resistors 120, 125 may be within one one-hundredth of a percent to improve a total harmonic distortion (THD) of the multi-class modulator circuitry 110. Advantageously, decreasing differences between resistances of the resistors 120, 125 improves the THD of the differential output signal.

The class D amplifier circuitry 130 has first and second inputs coupled to the audio source 105 by the conditioning circuitry 115. Also, the first and second inputs of the class D amplifier circuitry 130 are coupled to outputs of the amplifier circuitries 130, 140 by the resistors 120, 125. The class D amplifier circuitry 130 has a third input coupled to the output of the class AB amplifier circuitry 140. The class D amplifier circuitry 130 receives the differential pair of input signals from the audio source 105. In some examples, the class D amplifier circuitry 130 receives filtered signals responsive to the first conditioning circuitry 115 filtering the differential pair of input signals. The class D amplifier circuitry 130 receives the differential pair of output signals. In some examples, the class D amplifier circuitry 130 receives combined signals including contributions from both the differential pair of input signals and the differential pair of output signals. In such examples, the class D amplifier circuitry 130 also receives the minus output signal.

The class D amplifier circuitry 130 amplifies and/or filters the differential pair of input signals and the differential pair of output signals to reduce noise, improve efficiency, improve total harmonic distortion, etc. In some examples, the class D amplifier circuitry 130 utilizes modulation circuitry (illustrated in FIGS. 2 and 3B) to implement a multi-order transfer function. In such examples, the modulation circuitry generates an output signal based on differences between the differential pair of input signals and the differential pair of output signals. The class D amplifier circuitry 130 may include circuitry to compensate the plus output signal for linear operations of the class AB amplifier circuitry 140. Such circuitry is illustrated in FIGS. 2, 3A, and 3B. The class D amplifier circuitry 130 uses PWM to generate a square waveform representative of the differential pair of input signals, feedback of the differential pair of output signals, and/or compensation signals. The class D amplifier circuitry 130 generates the plus output signal based on the square waveform.

In some examples, the class D amplifier circuitry 130 uses the square waveform to control switching to generate the plus output signal. For example, the class D amplifier circuitry 130 may use first and second switching of FETs (illustrated in FIG. 3A) to generate a square waveform as the plus output signal. In such an example, first switching corresponds to coupling the output of the class D amplifier circuitry 130 to a logic high (e.g., a logical one, a supply voltage), while second switching corresponds to coupling the output of the class D amplifier circuitry 130 to a logic low (e.g., a logical zero, a common potential). In the example of FIG. 1, the plus output signal of the class D amplifier circuitry 130 is a square waveform at least partially representative of the differential pair of input signals, feedback of the differential pair of output signals, and/or compensation signals. The class D amplifier circuitry 130 supplies the plus output signal to the amplifier circuitries 130, 140 and the filter circuitry 150. An example of the class D amplifier circuitry 130 is illustrated in FIGS. 2, 3A, and 3B.

The second conditioning circuitry 135 has first and second terminals coupled to the audio source 105 and the first conditioning circuitry 115. The second conditioning circuitry 135 has third and fourth terminals coupled to the class AB amplifier circuitry 140. The second conditioning circuitry 135 receives the differential pair of input signals at the first and second terminals. The second conditioning circuitry 135 filters the differential pair of input signals. In some examples, the second conditioning circuitry 135 is filter circuitry that removes signals of frequencies outside of a range of pass-through frequencies. In such examples, the second conditioning circuitry 135 may be low pass filter circuitry, band-pass filter circuitry, etc. The second conditioning circuitry 135 supplies the differential input signals to the class AB amplifier circuitry 140.

The class AB amplifier circuitry 140 has first and second inputs coupled to the audio source 105 by the conditioning circuitry 135. The class AB amplifier circuitry 140 has a third input coupled to the second resistor 125 and the amplifier circuitries 130, 140. The class AB amplifier circuitry 140 receives the differential pair of input signals from the audio source 105. In some examples, the class AB amplifier circuitry 140 receives filtered input signals from the second conditioning circuitry 135. The class AB amplifier circuitry 140 receives the minus output signal as feedback.

The class AB amplifier circuitry 140 amplifies the differential pair of input signals and/or contributions from the differential pair of output signals by a gain. The gain of the class AB amplifier circuitry 140 is a relatively large value. The class AB amplifier circuitry 140 generates a saturated output signal responsive to the relatively large gain. For example, the class AB amplifier circuitry 140 is capable of generating an output signal having voltages between a first supply voltage and a second supply voltage. In such examples, the class AB amplifier circuitry 140 clips the output signal to the first supply voltage for all input voltages that when amplified by the gain result in a voltage greater than first supply voltage. Such operations of the class AB amplifier circuitry 140 may be referred to as a saturation mode. While in saturation mode, the minus output signal of the class AB amplifier circuitry 140 is non-linear. Advantageously, the class AB amplifier circuitry 140 generates an output signal that is approximately equal to voltages of the first and second supplies responsive to the relatively high gain. Advantageously, configuring the class AB amplifier circuitry 140 to reduce durations of time that the output is linear increases power efficiency.

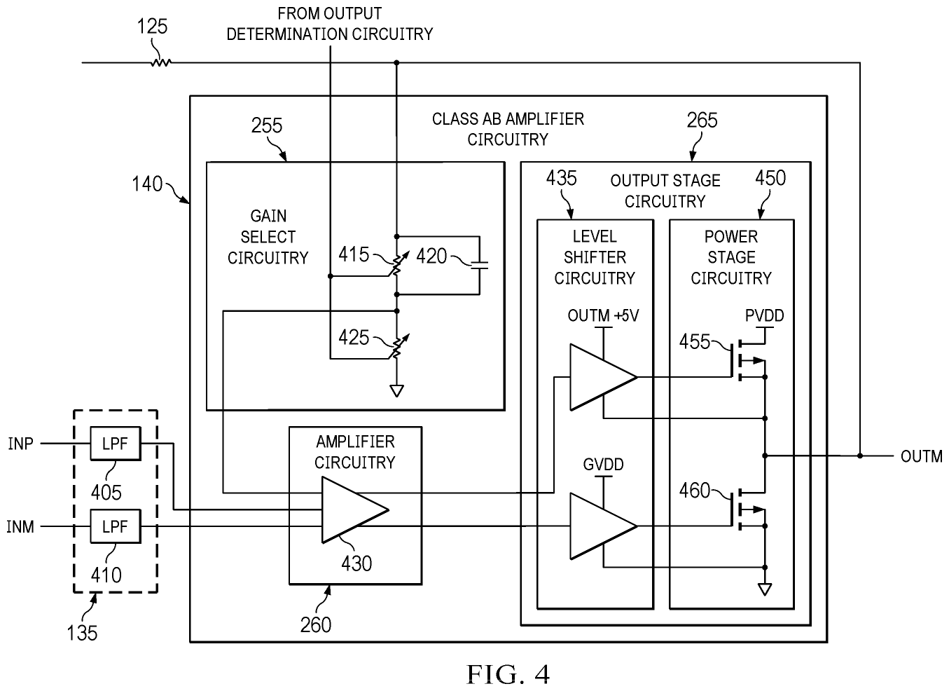

However, the class AB amplifier circuitry 140 may amplify relatively small voltages, such as voltages near a common potential, by the relatively high gain without clipping the output signal. Such operations of the output of the class AB amplifier circuitry 140 occur during transitions between supply voltages. During the transition between saturated voltages, the output of the class AB amplifier circuitry is linear. Accordingly, the class AB amplifier circuitry 140 is considered to be in a linear mode of operation. When supplied to power stage circuitry, the linear portions of the minus output signal of the class AB amplifier circuitry 140 may distort the audio signal. However, the class AB amplifier circuitry 140 supplies the minus output signal to the class D amplifier circuitry 130 to compensate the plus output signal for the linear portions of the minus output signal. Advantageously, the class D amplifier circuitry 130 reduces distortions by compensating the plus output signal for the linear portions of the minus output signal. An example of the class AB amplifier circuitry 140 is illustrated in FIGS. 2 and 4.

The filter circuitry 150 is coupled to the resistors 120, 125 and the amplifier circuitries 130, 140. The filter circuitry 150 receives the plus output signal from the class D amplifier circuitry 130 and the minus output signal from the class AB amplifier circuitry 140. The filter circuitry 150 filters the differential pair of output signals. The filter circuitry 150 supplies the filtered differential pair of output signals to the speaker 160 and/or the line out 170. An example of the filter circuitry 150 is illustrated in FIG. 2.

In some examples, the speaker 160 is coupled to the filter circuitry 150. The speaker 160 receives the filtered differential pair of output signals from the filter circuitry 150. The speaker 160 generates an audible noise responsive to the filtered differential pair of output signals. Alternatively, the filter circuitry 150 may be coupled to the line out 170. In such examples, the filter circuitry 150 supplies the filtered differential output signals to the line out 170 to allow external devices to be coupled to the audio system 100. For example, the line out 170 may be an auxiliary connection adaptive to couple an external amplifier to the audio system 100. In such an example, the multi-class modulation circuitry 110 may include circuitry to detect the external audio devices based on an increase in an impedance coupled to the filter circuitry 150. The multi-class modulation circuitry 110 adjusts the modulation of the class D amplifier circuitry 130 and a gain of the class AB amplifier circuitry 140 responsive to such a detection.

Although in the example of FIG. 1, the multi-class modulation circuitry 110 is implemented in the audio system 100, the multi-class modulation circuitry 110 may be implemented in alternative applications, such as driving loads that are not speakers.

FIG. 2 is a block diagram of an example of the multi-class modulation circuitry 110 of FIG. 1 including the conditioning circuitries 115, 135 of FIG. 1, the resistors 120, 125 of FIG. 1, and the amplifier circuitries 130, 140 of FIG. 1. In the example of FIG. 2, the multi-class modulation circuitry 110 includes the conditioning circuitries 115, 135, the resistors 120, 125, the amplifier circuitries 130, 140, example modulator circuitry 220, example combination circuitry 225, example feedforward circuitry 230, example comparison circuitry 235, first example output stage circuitry 240, example output detection circuitry 245, example gain select circuitry 255, example amplifier circuitry 260, and second example output stage circuitry 265. The multi-class modulation circuitry 110 is coupled to the filter circuitry 150 of FIG. 1. In the example of FIG. 2, the filter circuitry 150 includes an example inductor 270, a first example capacitor 275, and a second example capacitor 280.

The class D amplifier circuitry 130 is coupled to the first conditioning circuitry 115, the resistors 120, 125, the class AB amplifier circuitry 140, and the filter circuitry 150. The class D amplifier circuitry 130 is adaptive to be coupled to the audio source 105 of FIG. 1 by the conditioning circuitry 115. In the example of FIG. 2, the class D amplifier circuitry 130 includes the modulator circuitry 220, the combination circuitry 225, the feedforward circuitry 230, the comparison circuitry 235, the first output stage circuitry 240, and the output detection circuitry 245. Another example of the class D amplifier circuitry 130 is illustrated in FIGS. 3A and 3B.

The class AB amplifier circuitry 140 is coupled to the class D amplifier circuitry 130, the second resistor 125, the second conditioning circuitry 135, and the filter circuitry 150. The class AB amplifier circuitry 140 is adaptive to be coupled to the audio source 105 by the second conditioning circuitry 135. In the example of FIG. 2, the class AB amplifier circuitry 140 includes the gain select circuitry 255, the amplifier circuitry 260, and the second output stage circuitry 265. Another example of the class AB amplifier circuitry 140 is illustrated in FIG. 4.

The modulator circuitry 220 has a first input coupled to the first conditioning circuitry 115 and the first resistor 120. The modulator circuitry 220 has a second input coupled to the first conditioning circuitry 115 and the second resistor 125. The modulator circuitry 220 has second and third inputs coupled to the output detection circuitry 245. The modulator circuitry has first and second outputs coupled to the combination circuitry 225. The modulator circuitry 220 receives combined input signals from the first conditioning circuitry 115. In the example of FIG. 2, the combined input signals include the differential pair of input signals and the differential pair of output signals of the amplifier circuitries 130, 140. In some examples, the combined input signals are formed as an addition of one of the input signals of the differential pair with one of the output signals of the differential pair. For example, the modulator circuitry 220 receives a first combined signal approximately equal to the plus input signal and the plus output signal and a second combined signal approximately equal to the minus input signal and the minus output signal.

The modulator circuitry 220 modulates the combined differential signals to suppress errors between the differential pair of output signals and the differential pair of input signals. The modulator circuitry 220 generates first and second error signals based on differences between the differential output signal and the differential input signals. The first error signal represents differences between the plus input signal and the plus output signal, while the second error signal represents differences between the minus input signal and the minus output signal. Advantageously, the error signals are a differential representation of differences between the differential input signal and the differential output signal.

Components of the modulator circuitry 220 (illustrated in FIG. 3B) implement a multi-order transfer function that modulates the combined input signals. In some examples, the modulator circuitry 220 implements a relatively high order transfer function (e.g., a third order function) to modulate the combined input signals. However, inductor capacitor (LC) resonance responsive to coupling relatively large loads (e.g., loads greater than one-hundred Ohms ((2)) to the filter circuitry 150, increases the THD of the differential output signal. The modulator circuitry 220 improves the THD of the differential output signal by implementing a relatively lower order transfer function (e.g., from a third order to a second order). In some examples, reducing the order of the transfer function increases stability by dampening relatively high frequency LC resonance. In such examples, dampening frequencies of the LC resonance stabilizes the error signals of the modulator circuitry 220. In the example of FIG. 2, the order of the modulator circuitry 220 is configurable or adjustable, by the output detection circuitry 245. Advantageously, the modulator circuitry 220 may be modified to modulate the combined input signals based on a resistance of a load coupled to the filter circuitry 150.

The combination circuitry 225 a plurality of inputs coupled to the modulator circuitry 220. The combination circuitry 225 has first and second outputs coupled to the feedforward circuitry 230. The combination circuitry 225 receives the error signals from the modulator circuitry 220. The combination circuitry 225 determines a difference between the error signals from the modulator circuitry 220. The combination circuitry 225 combines the error signals from the modulator circuitry 220. The combination circuitry 225 supplies the combined error signals to the feedforward circuitry 230.

The feedforward circuitry 230 has first and second inputs coupled to the combination circuitry 225 and a third input coupled to the filter circuitry 150, the second resistor 125, the gain select circuitry 255, and the second output stage circuitry 265. The feedforward circuitry 230 has an output coupled to the comparison circuitry 235. The feedforward circuitry 230 receives the combined error signals from the combination circuitry 225. The feedforward circuitry 230 receives the minus output signal from the second output stage circuitry 265. The feedforward circuitry divides the minus output signal by a value greater than one to supply a signal of a logic level approximately of the comparison circuitry 235. The feedforward circuitry 230 generates a single ended error signal by combining the combined error signals with the divided minus output signal. In some examples, combining the combined error signals and the divided minus output signal results in a combined error signal that includes non-linearities of the minus output signal. Advantageously, the feedforward circuitry 230 accounts for non-ideal linearities of the minus output signal by offsetting the combined error signals by the minus output signal. The feedforward circuitry 230 supplies the combined error signal to the comparison circuitry 235.

In some examples, the feedforward circuitry 230 includes circuitry to adjust a common mode reference of the combined error signals. In such examples, the feedforward circuitry 230 may further include circuitry to adjust a logic level of the single ended error signal to a logic level of the comparison circuitry 235. Such an example of the feedforward circuitry 230 is illustrated in FIG. 3B. Advantageously, the feedforward circuitry 230 may offset the error combined signals and/or the divided minus output signal to adjust the single ended error signal. The feedforward circuitry 230 supplies the single ended error signal to the comparison circuitry 235.

The comparison circuitry 235 has an input coupled to the feedforward circuitry 230. The comparison circuitry 235 has an output coupled to the first output stage circuitry 240. The comparison circuitry 235 receives the single ended error signal from the feedforward circuitry 230. The comparison circuitry 235 compares the single ended error signal to a triangular signal to generate a square waveform as a comparison output. The comparison output of the comparison circuitry 235 has a varying duty cycle that is determined by the comparison of the combined error signal to the triangular signal. When the single ended error signal is greater than the triangular signal, the comparison circuitry 235 sets the comparison output to a logic high (e.g., logical one). When the combined error signal is less than the triangular signal, the comparison circuitry 235 sets the comparison output to a logic low (e.g., logical zero). Advantageously, the duty cycle of the comparison output is based on the combined error signal. Advantageously, averaging the comparison output generates a sine waveform adjusted for the combined error of the differential pair of input signals and the linearities of the minus output signal. The comparison circuitry 235 supplies the comparison output to the first output stage circuitry 240.

The first output stage circuitry 240 has an input coupled to the comparison circuitry 235. The first output stage circuitry 240 has an output coupled to the class AB amplifier circuitry 140, the filter circuitry 150, the first resistor 120, and the output detection circuitry 245. The first output stage circuitry 240 receives the comparison output from the comparison circuitry 235. The first output stage circuitry 240 generates the plus output signal based on the comparison output. In some examples, the first output stage circuitry 240 generates the plus output signal using a first power domain, while the comparison output is of a second power domain. In such examples, the first power domain may be a relatively high-power domain in comparison to the second power domain of the comparison output. For example, the first power domain may be a twelve-volt power domain while the second power domain may be a three-volt power domain. In such an example, a relatively low power supply may be used to generate the comparison output. Advantageously, relatively low power circuitry reduces the cost and increases the speed of the class D amplifier circuitry 130. The first output stage circuitry 240 supplies the plus output signal to the filter circuitry 150 and the first resistor 120.

The output detection circuitry 245 has a first input coupled to the minus output signal of the class AB amplifier circuitry 140. The output detection circuitry 245 has a first output coupled to the filter circuitry 150, the first resistor 120, and the first output stage circuitry 240. The output detection circuitry has second and third outputs coupled to the modulator circuitry 220. The output detection circuitry has a fourth output coupled to the class AB amplifier circuitry 140. The output detection circuitry 245 determines whether a resistance of a load coupled to the filter circuitry 150 is greater than a threshold resistance. In some examples, the output detection circuitry 245 sets the plus output signal to a fixed voltage. In such examples, the output detection circuitry 245 measures a voltage of the minus output signal responsive to the fixed voltage at the plus output signal. The output detection circuitry 245 determines a resistance of the load based on the fixed voltage and the measured voltage.

When the resistance of the load is less than the threshold resistance, the output detection circuitry 245 configures the modulator circuitry 220 for a relatively high order modulation and increases a gain of the class AB amplifier circuitry 140. For example, when the load is the speaker 160 of FIG. 1, the output detection circuitry 245 adjusts the modulator circuitry 220 to use a third order transfer function and sets a gain of the class AB amplifier circuitry 140 to approximately eighty. When the resistance of the load is greater than the threshold resistance, the output detection circuitry 245 configures the modulator circuitry 220 for a relatively low order modulation and decreases a gain of the class AB amplifier circuitry 140. For example, when the load is the load out 170 of FIG. 1, the output detection circuitry 245 adjusts the modulator circuitry 220 to use a second order transfer function and sets a gain of the class AB amplifier circuitry 140 to a minimum value. Advantageously, the output detection circuitry 245 allows the multi-class modulator circuitry 110 to be coupled to a wide range of possible loads without LC resonance destabilizing the class D amplifier circuitry 130.

The gain select circuitry 255 has a first input coupled to the second resistor 125, the feedforward circuitry 230, the output detection circuitry 245, and the second output stage circuitry 265. The gain select circuitry 255 has a second input coupled to the output detection circuitry 245. The gain select circuitry 255 has an output coupled to the amplifier circuitry 260. The gain select circuitry 255 sets a gain of the amplifier circuitry 260 based on the minus output signal and the detection of the output detection circuitry 245. When the output detection circuitry 245 detects a load of a resistance less than the threshold resistance, the gain select circuitry 255 configures the amplifier circuitry 260 to have a relatively high gain. In such a configuration, the relatively high gain of the gain select circuitry 255 configures the amplifier circuitry 260 for operation that saturates the minus output signal. When the output detection circuitry 245 detects a load of a resistance greater than the threshold resistance, the gain select circuitry 255 configures the amplifier circuitry 260 to have a relatively low gain. In such a configuration, the relatively low gain of the gain select circuitry 255 prevents the amplifier circuitry 260 from operating in a saturation condition.

The amplifier circuitry 260 has first and second inputs coupled to the second conditioning circuitry 135. The amplifier circuitry 260 has a third input coupled to the gain select circuitry 255. The amplifier circuitry 260 receives the differential pair of input signals from the second conditioning circuitry 135. The gain select circuitry 255 configures the gain of the amplifier circuitry 260. The amplifier circuitry 260 determines the difference between the differential pair of input signals. The amplifier circuitry 260 amplifies the difference between the differential input signal by the gain to generate the amplified output signal.

In some examples, relatively high gains configure the amplifier circuitry 260 for a saturation mode of operation. In the saturation mode of operation, the amplified output signal is approximately equal to a first supply value for input signals greater than a first value and is approximately equal to a second supply voltage for input signals less than a second value. The first and second values are approximately equal to the supply values divided by the relatively high gain. However, the amplifier circuitry 260 operates in a linear mode of operation for values between the first and second values. In the linear mode of operation, the input signals are transitioning between the first and second values. The gain is adjusted to a value that reduces an amount of time in the linear mode of operation. Ideally, configuring the amplifier circuitry 260 to only operate in the saturation mode of operation reduces linearity of the minus output. Advantageously, the feedforward circuitry 230 adjusts the plus output signal to account for the amplifier circuitry 260 being in the linear mode of operation.

The second output stage circuitry 265 has an input coupled to the amplifier circuitry 260. The second output stage circuitry 265 has an output coupled to the second resistor 125, the class D amplifier circuitry 130, the filter circuitry 150, the feedforward circuitry 230, the output detection circuitry 245, and the gain select circuitry 255. The second output stage circuitry 255 receives the amplified output from the comparison circuitry 235. The second output stage circuitry 265 generates the minus output signal based on the amplifier output. In some examples, the second output stage circuitry 265 generates the minus output signal using a first power domain, while the amplifier output is of a second power domain. In such examples, the first power domain may be a relatively high-power domain in comparison to the second power domain of the amplified output. For example, the first power domain may be a twelve-volt power domain while the second power domain may be a three-volt power domain. In such an example, relatively low power may be used to generate the amplified output. Advantageously, relatively low power circuitry reduces the cost and increases the speed of the class AB amplifier circuitry 140. The second output stage circuitry 265 supplies the minus output signal to the second resistor 125, the filter circuitry 150, the feedforward circuitry 230, the output detection circuitry 245, and the gain select circuitry 255.

The inductor 270 has a first terminal coupled to the first resistor 120 and the class D amplifier circuitry 130. The inductor 270 has a second terminal coupled to the first capacitor 275 and adaptive to be coupled to a load (e.g., the speaker 160 and/or the load out 170). The inductor 270 prevents spikes in an output current from being supplied to the load responsive to transitions of the plus output signal. The inductor 270 allows excess charge from current spikes to recirculate through the filter circuitry 150 opposed to being supplied to the load. The inductor 270 averages the plus output signal to convert the plus output signal from a square waveform to a sinusoid waveform. Advantageously, the inductor 270 increases the efficiency of the filter circuitry 150.

The first capacitor 275 has a first terminal coupled to the inductor 270 and adaptive to be coupled to the load. The first capacitor 275 has a second terminal coupled to the second resistor 125, the amplifier circuitries 130, 140, the second capacitor 280, and adaptive to be coupled to the load. The first capacitor 275 averages relatively high frequency signals of the differential output signal. In some examples, the relatively high frequency signals are noise on the differential output signal.

The second capacitor 280 has a first terminal coupled to the second resistor 125, the amplifier circuitries 130, 140, the first capacitor 275, and adaptive to be coupled to a load. The second capacitor 280 has a second terminal coupled to a common terminal that supplies a common potential (e.g., ground). The second capacitor 280 averages relatively high frequency signals of the minus output signal. In some examples, the relatively high frequency signals are noise on the minus output signal.

FIGS. 3A and 3B are a schematic diagram of examples of the first conditioning circuitry 115 of FIGS. 1 and 2, the class D amplifier circuitry 130 of FIGS. 1 and 2, the modulator circuitry 220 of FIG. 2, the combination circuitry 225 of FIG. 2, the feedforward circuitry 230 of FIG. 2, the comparison circuitry 235 of FIG. 2, the first output stage circuitry 240 of FIG. 2, and the output detection circuitry 245 of FIG. 2. In the example of FIG. 3B, the first conditioning circuitry 115 includes a third example resistor 302, a fourth example resistor 304, a first example capacitor 306, a fifth example resistor 308, and a sixth example resistor 310.

In the example of FIG. 3B, the modulator circuitry 220 includes a first example amplifier 312, a second example capacitor 314, a third example capacitor 316, a first example switch 318, a second example switch 320, a seventh example resistor 321, an eighth example resistor 322, a fourth example capacitor 323, a third example switch 324, a fifth example capacitor 325, a fourth example switch 326, a second example amplifier 327, a sixth example capacitor 328, a seventh example capacitor 330, a fifth example switch 332, a sixth example switch 333, a seventh example switch 334, an eighth example switch 335, a ninth example resistor 336, a tenth example resistor 338, an eleventh example resistor 340, a ninth example switch 342, a twelfth example resistor 344, a tenth example switch 346, a third example amplifier 348, an eighth example capacitor 350, a ninth example capacitor 352, an eleventh example switch 354, and a twelfth example switch 356.

In the example of FIG. 3B, the combination circuitry 225 includes a first example variable resistor 357, a second example variable resistor 358, a thirteenth example resistor 359, a third example variable resistor 360, a fourth example amplifier 361, a fourth example variable resistor 362, a fifth example variable resistor 363, a fourteenth example resistor 364, and a sixth example variable resistor 365. In the example of FIG. 3B, the feedforward circuitry 230 includes a fifteenth example resistor 366, a fifth example amplifier 367, a sixteenth example resistor 368, a seventeenth example resistor 369, an eighteenth example resistor 370, a nineteenth example resistor 371, example divider circuitry 372, a twentieth example resistor 373.

In the example of FIG. 3A, the comparison circuitry 235 includes a sixth example amplifier 374 and an example triangular signal 375. In the example of FIG. 3A, the first output stage circuitry 240 includes example logic driver circuitry 376, first example level shifting circuitry 377, second example level shifting circuitry 378, example power stage circuitry 379, a first example driver 380, a first example transistor 381, a second example driver 382, and a second example transistor 383. In the example of FIG. 3B, the output detection circuitry 245 includes an example digital-to-analog converter (DAC) 384, an example analog-to-digital converter (ADC) 385, example resistance determination circuitry 386, and example controller circuitry 388.

The third resistor 302 has a first terminal adaptive to be coupled to the audio source 105 of FIG. 1. The third resistor 302 has a second terminal coupled to the fourth resistor 304 and the first capacitor 306. The fourth resistor 304 has a first terminal coupled to the third resistor 302 and the first capacitor 306. The fourth resistor 304 has a second terminal coupled to the first resistor 120 and the modulator circuitry 220. The first capacitor 306 has a first terminal coupled to the resistors 302, 304. The first capacitor 306 has a second terminal coupled to the resistors 302, 304. The fifth resistor 308 has a first terminal adaptive to be coupled to the audio source 105. The fifth resistor 308 has a second terminal coupled to the first capacitor 306 and the sixth resistor 310. The sixth resistor 310 has a first terminal coupled to the first capacitor 306 and the fifth resistor 308. The sixth resistor 310 has a second terminal coupled to the second resistor 125 and the modulator circuitry 220.

The third resistor 302 receives the plus input signal from the audio source 105 while the fifth resistor 308 receives the minus input signal from the audio source 105. The resistors 302, 308 and the first capacitor 306 filter relatively high frequency noise of the differential pair of input signals. In some examples, the resistors 302, 308 and the capacitor 306 may be referred to as a low pass filter. Advantageously, the resistors 302, 308 and the capacitor 306 reduce relatively high frequency noise.

The fourth resistor 304 receives the filtered plus input signal from while the sixth resistor 310 receives the filtered minus input signal. Also, the fourth resistor 304 receives the plus output signal from the first resistor 120 while the sixth resistor 310 receives the minus output signal from the second resistor 125. The resistors 304, 310 combine the filtered differential pair of input signals with the differential pair of output signals. In some examples, the resistors 304, 310 may be referred to as summing resistors. The resistors 304, 310 supply the combined signals to the modulator circuitry 220.

The first amplifier 312 has a first input coupled to the first conditioning circuitry 115, the first resistor 120, and the second capacitor 314. The first amplifier 312 has a second input coupled to the first conditioning circuitry 115, the second resistor 125, and the third capacitor 316. The first amplifier 312 has a first output coupled to the second capacitor 314, the first switch 318, and the seventh resistor 321. The first amplifier 312 has a second output coupled to the third capacitor 316, the second switch 320, and the eighth resistor 322.

The second capacitor 314 has a first terminal coupled to the first conditioning circuitry 115, the first resistor 120, and the first amplifier 312. The second capacitor 314 has a first terminal coupled to the first amplifier 312, the first switch 318, and the seventh resistor 321. The third capacitor 316 has a first terminal coupled to the first conditioning circuitry 115, the second resistor 125, and the first amplifier 312. The third capacitor 316 has a second terminal coupled to the first amplifier 312, the second switch 320, and the eighth resistor 322.

The first amplifier 312 receives the combined signals from the resistors 304, 310. The capacitors 314, 316 provide frequency dependent feedback to the inputs of the first amplifier 312. The first amplifier 312 and the capacitors 314, 316 integrate the combined signals. In some examples, the first amplifier 312 and the capacitors 314, 316 are described as integrator circuitry. The first amplifier 312 supplies first order integrated signals to the switches 318, 320 and the resistors 321, 322.

The first switch 318 has a first terminal coupled to the first amplifier 312, the second capacitor 314, the seventh resistor 321, and the fourth capacitor 323. The first switch 318 has a second terminal coupled to the first variable resistor 357. The first switch 318 has a control terminal coupled to the controller circuitry 388. The second switch 320 has a first terminal coupled to the first amplifier 312, the third capacitor 316, the eighth resistor 322, and the fifth capacitor 325. The second switch 320 has a second terminal coupled to fourth variable resistor 362. The second switch 320 has a control terminal coupled to the controller circuitry 388. When closed, the switches 318, 320 couple the first order integrated signals from the first amplifier 312 to the combination circuitry 225. When open, the switches 318, 320 prevent the first order integrated signals from being coupled to the combination circuitry 225.

The seventh resistor 321 has a first terminal coupled to the first amplifier 312, the first switch 318, and the capacitors 314, 323. The seventh resistor 321 has a second terminal coupled to the third switch 324, the second amplifier 327, the sixth capacitor 328, and the eleventh resistor 340. The eighth resistor 322 has a first terminal coupled to the first amplifier 312, the second switch 320, and the capacitors 316, 325. The eighth resistor 322 has a second terminal coupled to the fourth switch 326, the second amplifier 327, the seventh capacitor 330, and the twelfth resistor 344.

The resistors 321, 322 receive the first order integrated signals from the first amplifier 312. The capacitors 314, 316 and the resistors 321, 322 form high pass filter circuitry. The capacitors 314, 316 and the resistors 321, 322 filter relatively low frequency signals from the first order integrated signals. Also, the resistors 321, 322 combine the filtered first order integrated signals with third order integrated signals when the switches 342, 346 are closed (e.g., conducting). In some examples, the resistors 321, 322 may be referred to as summing resistors. The resistors 321, 322 supply the combined integrated signals to the second amplifier 327.

The fourth capacitor 323 has a first terminal coupled to the first amplifier 312, the second capacitor 314, the first switch 318, and the seventh resistor 321. The fourth capacitor 323 has a second terminal coupled to the third switch 324. The third switch 324 has a first terminal coupled to the fourth capacitor 323 and a second terminal coupled to the resistors 321, 340, the second amplifier 327, and the sixth capacitor 328. The third switch 324 has a control terminal coupled to the controller circuitry 388.

The fifth capacitor 325 has a first terminal coupled to the first amplifier 312, the third capacitor 316, the second switch 320, and the eighth resistor 322. The fifth capacitor 325 has a second terminal coupled to the fourth switch 326. The fourth switch 326 has a first terminal coupled to the fifth capacitor 325 and a second terminal coupled to the resistors 322, 344, the second amplifier 327, and the seventh capacitor 330. The fourth switch 326 has a control terminal coupled to the controller circuitry 388.

When closed, the switches 324, 326 couple the first order integrated signals from the first amplifier 312 to inputs of the second amplifier 327 by the capacitors 323, 325. In such examples, the capacitors 323, 325 filter frequencies of the first order integrated signals. When open, the switches 324, 326 prevent the first order integrated signals from being coupled to inputs of the second amplifier 327.

The second amplifier 327 has a first input coupled to the resistors 321, 340 and the sixth capacitor 328. The second amplifier 327 has a second input coupled to the resistors 322, 344 and the seventh capacitor 330. The second amplifier 327 has a first output coupled to the sixth capacitor 328, the switches 332, 333, and the ninth resistor 336. The second amplifier 327 has a second output coupled to the seventh capacitor 330, the switches 334, 335, and the tenth resistor 338.

The sixth capacitor 328 has a first terminal coupled to the resistors 321, 340 and the second amplifier 327. The sixth capacitor 328 has a second terminal coupled to the second amplifier 327, the switches 332, 333, and the ninth resistor 336. The seventh capacitor 330 has a first terminal coupled to the resistors 322, 344 and the second amplifier 327. The seventh capacitor 330 has a second terminal coupled to the second amplifier 327, the switches 334, 335, and the tenth resistor 338.

The second amplifier 327 receives the combined integrated signals from the resistors 321, 322. The capacitors 328, 330 provide frequency dependent feedback to the inputs of the second amplifier 327. The second amplifier 327 and the capacitors 328, 330 integrate the combined integrated signals. In some examples, the second amplifier 327 and the capacitors 328, 330 are described as integrator circuitry. The second amplifier 327 supplies second order integrated signals to the switches 332, 333, 334, 335, and the resistors 336, 338.

The fifth switch 332 has a first terminal coupled to the second amplifier 327, the sixth capacitor 328, the sixth switch 333, and the ninth resistor 336. The fifth switch 332 has a second terminal coupled to the second variable resistor 358. The fifth switch 332 has a control terminal coupled to the controller circuitry 388. The sixth switch 333 has a first terminal coupled to the second amplifier 327, the sixth capacitor 328, the fifth switch 332, and the ninth resistor 336. The sixth switch 333 has a second terminal coupled to the resistors 359, 370 and the fourth amplifier 361. The sixth switch 333 has a control terminal coupled to the controller circuitry 388.

The seventh switch 334 has a first terminal coupled to the second amplifier 327, the seventh capacitor 330, the eighth switch 335, and the tenth resistor 338. The seventh switch 334 has a second terminal coupled to the fifth variable resistor 363. The seventh switch 334 has a control terminal coupled to the controller circuitry 388. The eighth switch 335 has a first terminal coupled to the second amplifier 327, the seventh capacitor 330, the seventh switch 334, and the tenth resistor 338. The eighth switch 335 has a second terminal coupled to the fourth amplifier 361 and the resistors 364, 366. The eighth switch 335 has a control terminal coupled to the controller circuitry 388.

When closed, the switches 332, 334 couple the second order integrated signals from the second amplifier 327 to the combination circuitry 225. When open, the switches 332, 334 prevent the second order integrated signals from being supplied to the combination circuitry 225. When closed, the switches 333, 335 couple the second order integrated signals from the second amplifier 327 to the feedforward circuitry 230. When open, the switches 333, 335 prevent the second order integrated signals from being supplied to the feedforward circuitry 230.

The ninth resistor 336 has a first terminal coupled to the second amplifier 327, the switches 332, 333, and the sixth capacitor 328. The ninth resistor 336 has a second terminal coupled to the third amplifier 348 and the eighth capacitor 350. The tenth resistor 338 has a first terminal coupled to the second amplifier 327, the switches 334, 335, and the seventh capacitor 330. The tenth resistor 338 has a second terminal coupled to the third amplifier 348 and the ninth capacitor 352.

The resistors 336, 338 receive the second order integrated signals from the second amplifier 327. The capacitors 328, 330 and the resistors 336, 338 form high pass filter circuitry. The capacitors 328, 330 and the resistors 336, 338 filter relatively low frequency signals from the second order integrated signals.

The eleventh resistor 340 has a first terminal coupled to the seventh resistor 321, the second amplifier 327, and the sixth capacitor 328. The eleventh resistor 340 has a second terminal coupled to the ninth switch 342. The ninth switch 342 has a first terminal coupled to the eleventh resistor 340. The ninth switch 342 has a second terminal coupled to the third amplifier 348, the eighth capacitor 350, and the eleventh switch 354. The ninth switch 342 has a control terminal coupled to the controller circuitry 388.

The eleventh resistor 340 and the ninth switch 342 form a feedback loop that may supply one of the third order integrated signals to the second amplifier 327. When the ninth switch 342 is closed (e.g., conducting), the eleventh resistor 340 and the ninth switch 342 couple the first output of the third amplifier 348 to the first input of the second amplifier 327. When the ninth switch 342 is open (e.g., non-conducting), the ninth switch 342 prevents the first output of the third amplifier 348 from being supplied to the first input of the second amplifier 327. In such examples, the eleventh resistor 340 stabilizes timing of the feedback loop.

The twelfth resistor 344 has a first terminal coupled to the eighth resistor 322, the second amplifier 327, and the seventh capacitor 330. The twelfth resistor 344 has a second terminal coupled to the tenth switch 346. The tenth switch 346 has a first terminal coupled to the twelfth resistor 344. The tenth switch 346 has a second terminal coupled to the third amplifier 348, the ninth capacitor 352, and the twelfth switch 356. The tenth switch 346 has a control terminal coupled to the controller circuitry 388.

The twelfth resistor 344 and the tenth switch 346 form a feedback loop that may supply one of the third order integrated signals to the second amplifier 327. When the tenth switch 346 is closed (e.g., conducting), the twelfth resistor 344 and the tenth switch 346 couple the second output of the third amplifier 348 to the second input of the second amplifier 327. When the tenth switch 346 is open (e.g., non-conducting), the tenth switch 346 prevents the second output of the third amplifier 348 from being supplied to the second input of the second amplifier 327. In such examples, the twelfth resistor 344 stabilizes timing of the feedback loop.

The third amplifier 348 has a first input coupled to the ninth resistor 336 and the eighth capacitor 350. The third amplifier 248 has a second input coupled to the tenth resistor 338 and the ninth capacitor 352. The third amplifier 248 has a first output coupled to the switches 342, 354 and the eighth capacitor 350. The third amplifier 348 has a second output coupled to the switches 346, 356 and the ninth capacitor 352.

The eighth capacitor 350 has a first terminal coupled to the ninth resistor 336 and the third amplifier 348. The eighth capacitor 350 has a second terminal coupled to the switches 342, 354 and the third amplifier 348. The ninth capacitor 352 has a first terminal coupled to the tenth resistor 338 and the third amplifier 348. The ninth capacitor 352 has a second terminal coupled to the switches 346, 356 and the third amplifier 348.

The third amplifier 348 receives the second order integrated signals from the resistors 336, 338. The capacitors 350, 352 provide frequency dependent feedback to the inputs of the third amplifier 348. The third amplifier 348 and the capacitors 350, 352 integrate the second order integrated signals. In some examples, the third amplifier 348 and the capacitors 350, 352 are described as integrator circuitry. The third amplifier 348 supplies third order integrated signals to switches 342, 346, 354, 356.

The eleventh switch 354 has a first terminal coupled to the ninth switch 342, the third amplifier 348, and the eighth capacitor 350. The eleventh switch 354 has a second terminal coupled to third variable resistor 360. The eleventh switch 354 has a control terminal coupled to the controller circuitry 388. The twelfth switch 356 has a first terminal coupled to the tenth switch 346, the third amplifier 348, and the ninth capacitor 352. The twelfth switch 356 has a second terminal coupled to the sixth variable resistor 365. The twelfth switch 356 has a control terminal coupled to the controller circuitry 388.

The switches 354, 356 receive the third order integrated signals from the third amplifier 348. When closed, the switches 354, 356 supply the third order integrated signals to the variable resistors 360, 365 of the combination circuitry 225. When open, the switches 354, 356 prevent the third amplifier 348 from supplying the third order integrated signals to the combination circuitry 225.

The first variable resistor 357 has a first terminal coupled to the first switch 318 and a second terminal coupled to the variable resistors 358, 360, the thirteenth resistor 359, and the fourth amplifier 361. In some examples, the first variable resistor 357 has a control terminal coupled to the controller circuitry 388. In such examples, the controller circuitry 388 may configure the resistance of the first variable resistor 357.

The second variable resistor 358 has a first terminal coupled to the fifth switch 332 and a second terminal coupled to the variable resistors 357, 360, the thirteenth resistor 359, and the fourth amplifier 361. In some examples, the second variable resistor 358 has a control terminal coupled to the controller circuitry 388. In such examples, the controller circuitry 388 may configure the resistance of the second variable resistor 358. The thirteenth resistor 359 has a first terminal coupled to the variable resistors 357, 358, 360 and the fourth amplifier 361 and a second terminal coupled to the sixth switch 333, the fourth amplifier 361, and the eighteenth resistor 370.

The third variable resistor 360 has a first terminal coupled to the eleventh switch 354 and a second terminal coupled to the first variable resistor 357 and the fourth amplifier 361. In some examples, the third variable resistor 360 has a control terminal coupled to the controller circuitry 388. In such examples, the controller circuitry 388 may configure the resistance of the third variable resistor 360.

The fourth amplifier 361 has a first input coupled to the variable resistors 357, 358, 360 and the thirteenth resistor 359 and a second input coupled to the variable resistors 362, 365. The fourth amplifier 361 has a first output coupled to the sixth switch 333 and the resistors 359, 370. The fourth amplifier 361 has a second output coupled to the eighth switch 335 and the resistors 364, 366.

The fourth variable resistor 362 has a first terminal coupled to the second switch 320 and a second terminal coupled to the fourth amplifier 361, the variable resistors 363, 365, and the fourteenth resistor 364. In some examples, the fourth variable resistor 362 has a control terminal coupled to the controller circuitry 388. In such examples, the controller circuitry 388 may configure the resistance of the fourth variable resistor 362.

The fifth variable resistor 363 has a first terminal coupled to the seventh switch 334 and a second terminal coupled to the fourth amplifier 361, the variable resistors 362, 365, and the fourteenth resistor 364. In some examples, the fifth variable resistor 363 has a control terminal coupled to the controller circuitry 388. In such examples, the controller circuitry 388 may configure the resistance of the fifth variable resistor 363. The fourteenth resistor 364 has a first terminal coupled to the fourth amplifier 361 and the variable resistors 362, 363, 365 and a second terminal coupled to the eighth switch 335, the fourth amplifier 361, and the fifteenth resistor 366.

The sixth variable resistor 365 has a first terminal coupled to the twelfth switch 356 and a second terminal coupled to the fourth amplifier 361, the variable resistors 362, 363, and the fourteenth resistor 364. In some examples, the sixth variable resistor 365 has a control terminal coupled to the controller circuitry 388. In such examples, the controller circuitry 388 may configure the resistance of the sixth variable resistor 365.

In the example of FIG. 3B, the variable resistors 357, 362 have a first resistance representative of a first parameter (a1) of the first order integrated signals from the modulator circuitry 220. In some examples, the first parameter may correspond to a first order coefficient of a transfer function. In such examples, the resistances of the variable resistors 357, 362 may be modified based on a mode of operation of the modulator circuitry 220. Advantageously, contributions of the first order integrated signals to an error signal generated by the fourth amplifier 361 may be modified by the variable resistors 357, 362.

In the example of FIG. 3B, the variable resistors 358, 363 have a second resistance representative of a second parameter (a2) of the second order integrated signals from the modulator circuitry 220. In some examples, the second parameter may correspond to a second order coefficient of a transfer function. In such examples, the resistances of the variable resistors 358, 363 may be modified based on a mode of operation of the modulator circuitry 220. For example, the second resistance of the variable resistors 358, 363 may be a first value for a third order modulation and a second value for a second order modulation. Advantageously, contributions of the second order integrated signals to an error signal generated by the fourth amplifier 361 may be modified by the variable resistors 358, 363.

In the example of FIG. 3B, the variable resistors 360, 365 have a third resistance representative of a third parameter (a3) of the third order integrated signals from the modulator circuitry 220. In some examples, the third parameter may correspond to a third order coefficient of a transfer function. In such examples, the resistances of the variable resistors 360, 365 may be modified based on a mode of operation of the modulator circuitry 220. Advantageously, contributions of the third order integrated signals to an error signal generated by the fourth amplifier 361 may be modified by the variable resistors 360, 365.

The fourth amplifier 361 combines contributions from the variable resistors 357, 358, 360, 362, 363, 365 to generate a differential pair of error signals. The fourth amplifier 361 isolates the modulator circuitry 220 from the feedforward circuitry 230. The fourth amplifier 361 supplies the differential pair of error signals to the resistors 366, 370.

The fifteenth resistor 366 has a first terminal coupled to the eighth switch 335, the fourth amplifier 361, and the fourteenth resistor 364. The fifteenth resistor 366 has a second terminal coupled to the fifth amplifier 367 and the resistors 368, 369. The fifteenth resistor 366 receives a first error signal of the differential pair of error signals from the combination circuitry 225.

The fifth amplifier 367 has a first input coupled to the resistors 366, 368, 369 and a second input coupled to the resistors 370, 371, 373. The fifth amplifier 367 has an output coupled to the sixteenth resistor 368 and the sixth amplifier 374.

The sixteenth resistor 368 has a first terminal coupled to the amplifiers 367, 374 and a second terminal coupled to the fifth amplifier 367 and the resistors 366, 369. The sixteenth resistor 368 couples the input and output of the fifth amplifier 367. The sixteenth resistor 368 stabilizes timing of the loop formed between the input and output of the fifth amplifier 367. In some examples, the sixteenth resistor 368 may be described and/or referred to as a feedback resistor. Also, a resistance of the sixteenth resistor 368 may set a gain of the fifth amplifier 367.

The seventeenth resistor 369 has a first terminal coupled to the resistors 366, 368 and the fifth amplifier 367 and a second terminal coupled to a supply terminal that supplies a scaled power supply value (PVDD/N). The scaled power supply value is a voltage proportional to a power supply value (PVDD) of the power stage circuitry 379. In some examples, voltage divider circuitry is coupled between the seventeenth resistor 369 and the supply of the power stage circuitry 379 to generate the scaled power supply value. In other examples, another resistor is coupled between the seventeenth resistor 369 and the supply of the power stage circuitry 379 to form a voltage divider.

The eighteenth resistor 370 has a first terminal coupled to the sixth switch 333, the fourth amplifier 361, and the thirteenth resistor 359. The eighteenth resistor 370 has a second terminal coupled to the fifth amplifier 367 and the resistors 371, 373. The eighteenth resistor 370 receives a second error signal of the differential pair of error signals from the combination circuitry 225.

The nineteenth resistor 371 has a first terminal coupled to the fifth amplifier 367 and the resistors 370, 373 and a second terminal coupled to a common mode terminal that supplies a common mode voltage (VCM). The common mode voltage represents the target common mode voltage of the differential pair of error signals from the combination circuitry 225. In some examples, voltage divider circuitry is coupled between the nineteenth resistor 371 and the differential pair of error signals to determine the common mode voltage. In other examples, the common mode voltage is approximately equal to a common mode voltage of the triangular signal 375. Advantageously, the common mode voltage may adjust a direct current (DC) offset of the output of the fifth amplifier 367.

The divider circuitry 372 has an input coupled to the class AB amplifier circuitry 140 and the output determination circuitry 245. The divider circuitry 372 has an output coupled to the twentieth resistor 373. The divider circuitry 372 receives the minus output signal from the class AB amplifier circuitry 140. The divider circuitry 372 divides the minus output signal by a scalar value to generate a scaled minus output signal. In some examples, the scalar value of the divider circuitry 372 is determined by the logic level of the comparison circuitry 235 and/or the combination circuitry 225. In such examples, the scalar value allows the divider circuitry 372 to supply a relatively lower power version of the minus output signal to the fifth amplifier 367. The twentieth resistor 373 has a first terminal coupled to the divider circuitry 372 and a second terminal coupled to the fifth amplifier 367 and the resistors 370, 371.

The resistors 366, 368, 369 combine the first error signal, the scaled supply voltage, and an output of the fifth amplifier 367. The resistors 370, 371, 373 combine the second error signal, the common mode voltage, and the scaled minus output signal. The fifth amplifier 367 generates a combined error signal based on voltages supplied by the resistors 366, 368, 369, 370, 371, 373. The combined error signal combines the differential pair of error signals from the modulator circuitry 220 with non-linearities of the minus output signal. Also, the fifth amplifier 367 determines the combined error signal with voltages between the scaled supply voltage from the seventeenth resistor 369 and the common mode voltage from the nineteenth resistor 371. Advantageously, the class D amplifier circuitry 130 accounts for non-linear operations of the minus output signal responsive to supplying the combined error signal to the comparison circuitry 235.

The sixth amplifier 374 has a first input coupled to the fifth amplifier 367 and the sixteenth resistor 368. The sixth amplifier 374 has a second input coupled to the triangular signal 375. The sixth amplifier 374 has an output coupled to the logic driver circuitry 376. The sixth amplifier 374 receives the combined error signal from fifth amplifier 367. The sixth amplifier 374 receives the triangular signal 375 at the second input. The triangular signal 375 is a triangular waveform of a fixed frequency. The fixed frequency of the triangular signal 375 corresponds to a relatively high switching frequency of the plus output signal. In some examples, the fixed frequency of the triangular signal 375 is referred to as a carrier frequency. The sixth amplifier 374 supplies a modulated signal to the logic driver circuitry 376.

The sixth amplifier 374 compares the combined error signal to the triangular signal 375. In some examples, the sixth amplifier 374 sets the modulated signal to a logic high (e.g., logical one) when the combined error signal is greater than the triangular signal 375. In such examples, the sixth amplifier 374 sets the modulated signal to a logic low (e.g., logical zero) when the combined error signal is less than the triangular signal 375. The sixth amplifier 374 uses pulse width modulation (PWM) to generate the modulated signal. In some examples, PWM uses a duty cycle of a signal to represent data. In the example of FIG. 3A, the duty cycle of the modulated signal is proportional to the magnitude of the combined error signal. In some examples, the sixth amplifier 374 generates a plurality of relatively high duty cycle pulses responsive to a magnitude of the combined error signal being approximately equal to the amplitude of the triangular signal 375. In such examples, the sixth amplifier 374 generates a plurality of relatively low duty cycle pulses responsive to a magnitude of the combined error signal being substantially less than the amplitude of the triangular signal 375.

Advantageously, the sixth amplifier 374 converts the sinusoidal waveform of the combined error signal into a discrete signal using PWM. Advantageously, the combined error signal may be reconstructed by averaging the modulated signal. Advantageously, using a relatively high carrier frequency (e.g., the fixed frequency of the triangular signal 375) increases noise immunity.

The logic driver circuitry 376 has an input coupled to the sixth amplifier 374. The logic driver circuitry 376 has outputs coupled to the level shifting circuitries 377, 378. The logic driver circuitry 376 receives the modulated signal from the sixth amplifier 374. The logic driver circuitry 376 creates a differential pair of driver signals based on the modulated signal. In some examples, the logic driver circuitry 376 creates the differential pair of driver signals by converting the single ended modulated signal into a differential signal. In such examples, the logic driver circuitry 376 adjusts the differential version of the modulated signal to prevent overlapping times between signals of the differential pair of driver signals. Such durations to prevent overlapping times may be referred to as dead time. Advantageously, dead time prevents the transistors 381, 383 of the power stage circuitry 379 from being enabled at the same time. Advantageously, dead time increases power efficiency by reducing crossover durations.

The first level shifting circuitry 377 has an input coupled to the logic driver circuitry 376. The first level shifting circuitry 377 has an output coupled to first driver 380. The first level shifting circuitry 377 receives a first driver signal of the differential pair of driver signals from the logic driver circuitry 376. The second level shifting circuitry 378 has an input coupled to the logic driver circuitry 376. The second level shifting circuitry 378 has an output coupled to second driver 382. The second level shifting circuitry 378 receives a second driver signal of the differential pair of driver signals from the logic driver circuitry 376.

The level shifting circuitries 377, 378 increase the logic level of the differential pair of driver signals to generate a differential pair of switching signals capable of controlling relatively high-power transistors, such as the transistors 381, 383. In some examples, the level shifting circuitries 377, 378 increase the drive strength of the differential pair of driver signals using amplifiers configured as buffers. In such examples, the amplifiers of the level shifting circuitries 377, 378 may amplify the differential pair of driver signals using relatively high voltage supplies and/or in reference to voltages of switching circuitry (e.g., the transistors 381, 383). The level shifting circuitries 377, 378 supply the differential pair of switching signals to the power stage circuitry 379. Advantageously, the logic level of the circuitries 220, 225, 230, 235 may be substantially less than the logic level of the first output stage circuitry 240.

The power stage circuitry 379 is coupled between the level shifting circuitries 377, 378 and the filter circuitry 150. In the example of FIG. 3B, the power stage circuitry 379 includes the first driver 380, the first transistor 381, the second driver 382, and the second transistor 383. The power stage circuitry 379 receives the differential pair of switching signals from the level shifting circuitries 377, 378. The power stage circuitry 379 switches the transistors 381, 383 to generate the plus output signal.

The first driver 380 has an input coupled to the first level shifting circuitry 377 and an output coupled to the first transistor 381. The first driver 380 has a supply reference coupled to the transistors 381, 383. The first transistor 381 has a first current terminal coupled to a power supply value (PVDD). The power supply value is a voltage of the plus output signal. In some examples, the power supply voltage is a fixed voltage supplied by a power supply. The first transistor 381 has a second current terminal coupled to the first driver 380 and the second transistor 383. The first transistor 381 has a control terminal coupled to the first driver 380.

The second driver 382 has an input coupled to the second level shifting circuitry 378 and an output coupled to the second transistor 383. The second driver 382 has a supply reference coupled to the common terminal that supplies the common potential. The second transistor 383 has a first current terminal coupled to the first driver 380 and the first transistor 381. The second transistor 383 has a second current terminal coupled to the common terminal. The second transistor 383 has a control terminal coupled to the second driver 382.

The drivers 380, 382 receive the differential pair of switching signals from the level shifting circuitries 377, 378. The drivers 380, 382 control the transistors 381, 383 based on switching signals of the differential pair of switching signals. The transistors 381, 383 generate the plus output signal by setting the plus output signal to one of the power supply value or the common potential. In an example operation, the switching signals correspond to a first switching operation where the first transistor 381 sets the plus output signal approximately equal to the power supply value. In another example operation, the switching signals correspond to a second switching operation where the second transistor 383 sets the plus output signal approximately equal to the common potential. Advantageously, the transistors 381, 383 may be relatively high voltage transistors responsive to the shift in the logic level of the differential switching signal by the level shifting circuitries 377, 378 and the drivers 380, 382. Advantageously, the power stage circuitry 379 generates the plus output signal based on the PWM of the modulated signal from the comparison circuitry 235.

The DAC 384 has an input coupled to the controller circuitry 388. The DAC 384 has an output adaptive to be coupled to the plus output signal of the class D amplifier circuitry 130 and the filter circuitry 150. The DAC 384 receives a digital value from the controller circuitry 388. The DAC 384 converts the digital value to an analog voltage. The DAC 384 sets the plus output signal approximately equal to the analog voltage. Advantageously, the DAC 384 supplies the analog voltage to the filter circuitry 150 by the plus output signal. In some examples, the DAC 384 sets the plus output signal during durations where the first output stage circuitry 240 is not setting the plus output signal.

The ADC 385 has an input adaptive to be coupled to the minus output signal of the class AB amplifier circuitry 140 and the filter circuitry 150. The ADC 385 has an output coupled to the resistance determination circuitry 386. The ADC 385 samples the minus output signal responsive to the DAC 384 setting the plus output signal. The ADC 385 converts the sampled minus output signal value from an analog value to a digital value that represents the sampled minus output signal value. The ADC 385 supplies the digital value to the resistance determination circuitry 386.

The resistance determination circuitry 386 has an input coupled to the ADC 385. The resistance determination circuitry 386 has an output coupled to the controller circuitry 388. The resistance determination circuitry 386 receives the digital value from the ADC 385. The resistance determination circuitry 386 compares the digital value of the sampled minus output signal to the digital value supplied to the DAC 384. The resistance determination circuitry 386 determines whether a resistance of the load (e.g., the speaker 160 of FIG. 1 or the line out 170 of FIG. 1) coupled to the filter circuitry 150 is greater than a threshold resistance. When the resistance of the load is determined to be more than the threshold resistance, the resistance determination circuitry 386 determines the load to be the line out 170. However, when the resistance of the load is determined to be less than the threshold resistance, the resistance determination circuitry 386 determines the load to be the speaker 160. The resistance determination circuitry 386 indicates whether the resistance of the load is greater than the threshold resistance to the controller circuitry 388.

The controller circuitry 388 has an input coupled to the resistance determination circuitry 386. The controller circuitry 388 has a first output adaptive to be coupled to the class AB amplifier circuitry 140. In some examples, the controller circuitry 388 has second outputs coupled to the variable resistors 357, 358, 360, 362, 363, 365. The controller circuitry 388 has third outputs coupled to the switches 318, 320, 324, 326, 332, 333, 334, 335, 342, 346, 354, 356. The controller circuitry 388 has fourth outputs coupled to the DAC 384. The controller circuitry 388 supplies the digital value to the DAC 384 to determine a resistance of the load. The controller circuitry 388 receives an indication from the resistance determination circuitry 386 that identifies a resistance of the load to be greater than or less than the threshold resistance. The controller circuitry 388 controls the gain of the amplifier circuitry 260 of FIG. 2 and the second coefficient of the variable resistors 358, 363 based on the indication from the resistance determination circuitry 386. Also, the controller circuitry 388 controls the switches 318, 320, 324, 326, 332, 333, 334, 335, 342, 346, 354, 356 based on the indication from the resistance determination circuitry 386.

In example operation, the controller circuitry 388 closes the switches 318, 320, 332, 334, 342, 346, 354, 356 and opens the switches 324, 326, 333, 335 responsive to the resistance of the load being less than the threshold resistance. In such an example operation, the controller circuitry 388 configures the gain of the amplifier circuitry 260 and the resistances of the variable resistors 358, 363 to first values responsive to the resistance of the load being less than the threshold resistance. The controller circuitry 388 configures the modulator circuitry 220 to be third order modulator circuitry that implements a third order transfer function responsive to such example operations.

In another example operation, the controller circuitry 388 opens the switches 318, 320, 332, 334, 342, 346, 354, 356 and closes the switches 324, 326, 333, 335 responsive to the resistance of the load being greater than the threshold resistance. In such an example operation, the controller circuitry 388 configures the gain of the amplifier circuitry 260 and the resistances of the variable resistors 358, 363 to second values responsive to the resistance of the load being greater than the threshold resistance. The controller circuitry 388 configures the modulator circuitry 220 to be second order modulator circuitry that implements a second order transfer function responsive to such example operations. Advantageously, the controller circuitry 388 adjusts the order of the modulator circuitry 220 to compensate for LC resonance of a relatively high resistance load.

FIG. 4 is a schematic diagram of examples of the second conditioning circuitry 135 of FIGS. 1 and 2 and the class AB amplifier circuitry 140 of FIGS. 1 and 2. In the example of FIG. 4, the second conditioning circuitry 135 includes first low pass filter circuitry 405 and second low pass filter circuitry 410. In the example of FIG. 4, the class AB amplifier circuitry 140 includes the gain select circuitry 255 of FIG. 2, the amplifier circuitry 260 of FIG. 2, the second output stage circuitry 265 of FIG. 2, a first example variable resistor 415, an example capacitor 420, a second example variable resistor 425, a first example amplifier 430, example level shifting circuitry 435, a second example amplifier 440, a third example amplifier 445, example power stage circuitry 450, a first example transistor 455, a second example transistor 460.

The first low pass filter circuitry 405 has an input adaptive to be coupled to the audio source 105 of FIG. 1 and an output coupled to the first amplifier 430. The second low pass filter circuitry 410 has an input adaptive to be coupled to the audio source 105 and an output coupled to the first amplifier 430. The low pass filter circuitries 405, 410 receive the differential pair of input signals. The low pass filter circuitries 405, 410 filter relatively high frequency signals from the differential pair of input signals. The low pass filter circuitries 405, 410 supply the differential pair of input signals to the first amplifier 430.

The first variable resistor 415 has a first terminal coupled to the second resistor 125 of FIGS. 1 and 2, the output stage circuitry 265, and the capacitor 420. The first variable resistor 415 has a second terminal coupled to the capacitor 420, the second variable resistor 425, and the first amplifier 430. In some examples, the first variable resistor 415 has a control terminal adaptive to be coupled to the controller circuitry 388 of FIG. 3A. In such examples, the controller circuitry 388 may configure the resistance of the first variable resistor 415.

The capacitor 420 has a first terminal coupled to the second resistor 125, the output stage circuitry 265, and the first variable resistor 415. The capacitor 420 has a second terminal coupled to the variable resistors 415, 425 and the first amplifier 430.

The second variable resistor 425 has a first terminal coupled to the first variable resistor 415, the capacitor 420, and the first amplifier 430. The second variable resistor 425 has a second terminal coupled to the common terminal that supplies the common potential. In some examples, the second variable resistor 425 has a control terminal adaptive to be coupled to the controller circuitry 388. In such examples, the controller circuitry 388 may configure the resistance of the second variable resistor 425.

The variable resistors 415, 425 are configured as voltage divider circuitry. The resistances of the variable resistors 415, 425 set the gain of the first amplifier 430. In the example of FIG. 4, the variable resistors 415, 425 set a gain of the first amplifier 430 to a relatively high gain (e.g., eighty). In such examples, the relatively high gain of the variable resistors 415, 425 saturates the output of the first amplifier 430 for a relatively large range of input voltages. In some examples, the controller circuitry 388 may modify the resistances of the variable resistors 415, 425 to adjust the gain of the first amplifier 430.

The first amplifier 430 has first and second inputs adaptive to be coupled to the audio source 105 by the low pass filter circuitries 405, 410. The first amplifier 430 has a third input coupled to the variable resistors 415, 425 and the capacitor 420. The first amplifier 430 has a first output coupled to the second amplifier 440 and a second output coupled to the third amplifier 445. The first amplifier 430 receives the differential pair of input signals from the low pass filter circuitries 405, 410. The variable resistors 415, 425 set the gain of the first amplifier 430. The first amplifier 430 generates a differential pair of saturated output signals based on the gain and the input signals. The first amplifier 430 supplies the differential pair of saturated output signals to the amplifiers 440, 445.

The level shifting circuitry 435 is coupled to the first amplifier 430 and the power stage circuitry 450. In the example of FIG. 4, the level shifting circuitry 435 includes the amplifiers 440, 445. The level shifting circuitry 435 shifts the logic level of the differential pair of saturated output signals to a logic level capable of switching the transistors 455, 460.

The second amplifier 440 has an input coupled to the first amplifier 430 and an output coupled to the first transistor 455. The second amplifier 440 has a first supply input coupled to a minus output reference voltage (OUTM+5V) and a second supply input coupled to the transistors 455, 460. The minus output reference voltage is a voltage approximately five volts greater than the voltage of the minus output signal at any given time. In some examples, the class AB amplifier circuitry 140 includes charge pump circuitry coupled between the first and second supply inputs of the second amplifier 440 to generate the minus output reference voltage.

The third amplifier 445 has an input coupled to the first amplifier 430 and an output coupled to the second transistor 460. The third amplifier 445 has a first supply input coupled to a first power supply voltage (GVDD) and a second supply input coupled to the common terminal that supplies the common potential.

The amplifiers 440, 445 receive the differential pair of saturated output signals from the first amplifier 430. The amplifiers 440, 445 amplify the differential pair of saturated output signals based on the supply inputs. The second amplifier 440 generates a first switching signal, based on a first one of the saturated output signals, using voltages between the minus output reference voltage and the voltage of the minus output signal. The third amplifier 445 generates a second switching signal, based on a second one of the saturated output signals, using voltages between the first power supply voltage and the common potential. Advantageously, the voltages of the switching signals have a logic level of the transistors 455, 460.

The power stage circuitry 450 is coupled to the amplifiers 440, 445 and circuitry coupled to the minus output signal. In the example of FIG. 4, the power stage circuitry 450 includes the transistors 455, 460. The power stage circuitry 450 generates the minus output signal based on the switching signals from the level shifting circuitry 435.

The first transistor 455 has a first current terminal coupled to a second power supply voltage (PVDD) and a second current terminal coupled to the second amplifier 440, the second transistor 460, and circuitry coupled to the minus output signal. The first transistor 455 has a control terminal coupled to the second amplifier 440. The second transistor 460 has a first current terminal coupled to the second amplifier 440, the first transistor 455, and circuitry coupled to the minus output signal. The first transistor 455 has a second current terminal coupled to the common terminal and a control terminal coupled to the second amplifier 440.

The transistors 455, 460 set the minus output signal to voltages between the second power supply voltage and the common potential based on the switching signals from the amplifiers 440, 445. In some example operations, such as during saturation modes of operation, the transistors 455, 460 set the minus output signal to approximately one of the second power supply voltage or the common potential. In other example operations, such as during linear modes of operation, the transistors 455, 460 may be partially enabled and set the minus output signal to a voltage between the second power supply voltage and the common potential. When partially enabled, the transistors 455, 460 conduct a configurable amount of current responsive to changes in a transconductance of the transistors 455, 460. The transistors 455, 460 are considered to be fully enabled when the transconductance begins to stabilize and a fix current is being conducted by the transistors 455, 460. Advantageously, when in a saturation mode of operation, one of the transistors 455, 460 are fully enabled (e.g., conducting) while the other one of the transistors 455, 460 are fully disabled (e.g., non-conducting). Advantageously, fully enabling the transistors 455, 460 during saturation modes of operation improve power efficiency.

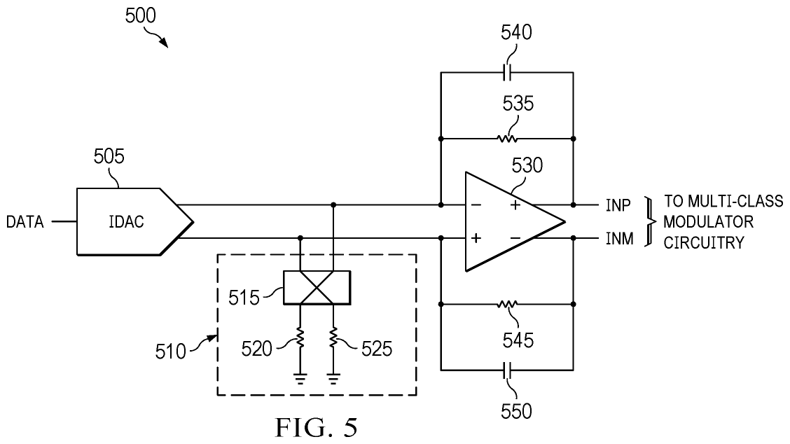

FIG. 5 is a schematic diagram of example conversion circuitry 500 to generate a differential input signal based on digital values. In the example of FIG. 5, the conversion circuitry 500 includes an example current digital-to-analog converter (IDAC) 505, example excess current circuitry 510, example switching circuitry 515, a first example resistor 520, a second example resistor 525, an example amplifier 530, a third example resistor 535, a first example capacitor 540, a fourth example resistor 545, and a second example capacitor 550. In some examples the conversion circuitry 500 receives digital values representative of an audio signal from the audio source 105 of FIG. 1. In some such examples, the conversion circuitry 500 is coupled between the audio source 105 and the multi-class modulation circuitry 110 of FIGS. 1 and 2. In other examples, the audio source 105 includes the conversion circuitry 500.

The IDAC 505 has an input adaptive to be coupled to a digital data source. For example, the IDAC 505 may be coupled to the audio source 105, when the audio source 105 supplies an audio signal as digital data. The IDAC 505 has first and second outputs coupled to the excess current circuitry 510, the amplifier 530, the resistors 535, 545, and the capacitors 540, 550. The IDAC 505 receives digital data (DATA) from the digital data source. In some examples, the digital data source may be a memory location, an external device, etc. The IDAC 505 converts the digital data to a differential analog current. The IDAC 505 supplies at least a portion of the differential analog current to the excess current circuitry and the amplifier 530.

The excess current circuitry 510 is coupled to the IDAC 505, the amplifier 530, the resistors 535, 545, and the capacitors 540, 550. In the example of FIG. 5, the excess current circuitry 510 includes the switching circuitry 515 and the resistors 520, 525. The excess current circuitry 510 provides a current path for excessive currents from the IDAC 505. In some examples, the excess current circuitry 510 is added to the conversion circuitry 500 based on the class of the IDAC 505. For example, the conversion circuitry 500 includes the excess current circuitry 510 responsive to the IDAC 505 being a class A IDAC. In such an example, the excess current path of the excess current circuitry 510 prevents charge accumulation resulting from excessive currents. In other examples, the conversion circuitry 500 does not include the excess current circuitry 510.

The switching circuitry 515 has a first terminal coupled to the IDAC 505, the amplifier 530, the third resistor 535, and the first capacitor 540. The switching circuitry 515 has a second terminal coupled to the IDAC 505, the amplifier 530, the fourth resistor 545, and the second capacitor 550. The switching circuitry 515 has a third terminal coupled to the first resistor 520. The switching circuitry 515 has a fourth terminal coupled to the second resistor 525. The switching circuitry 515 couples one of the first or second terminals to one of the third or fourth terminals to provide one or more paths for excess currents to flow. For example, the switching circuitry 515 may couple the first terminal to the third terminal and the second terminal to the fourth terminal. In such an example, the first terminal provides a first current path to the third terminal, while the second terminal provides a second current path to the fourth terminal. In some examples, the switching circuitry 515 switches the coupled terminals to balance a flow of current. In such examples, the switching circuitry balances non-ideal variations in the resistors 520, 525 across both current paths.

The first resistor 520 has a first terminal coupled to the switching circuitry 515 and a second terminal coupled to a common terminal that supplies a common potential (e.g., ground). The second resistor 525 has a first terminal coupled to the switching circuitry 515 and a second terminal coupled to the common terminal that supplies the common potential. The resistors 520, 525 provide a path for current to be sourced to the common potential. The resistance of the resistors 520, 525 may be referred to as pull-down resistors.

The amplifier 530 has a first input coupled to the IDAC 505, the switching circuitry 515, the third resistor 535, and the first capacitor 540. The amplifier 530 has a second input coupled to the IDAC 505, the switching circuitry 515, the fourth resistor 545, and the second capacitor 550. The amplifier 530 has a first output coupled to the third resistor 535, the first capacitor 540, and adaptive to be coupled to the multi-class modulator circuitry 110. The amplifier 530 has a second output coupled to the fourth resistor 545, the second capacitor 550, and adaptive to be coupled to the multi-class modulator circuitry 110.

The third resistor 535 has a first terminal coupled to the IDAC 505, the switching circuitry 515, the amplifier 530, and the first capacitor 540. The third resistor 535 has a second terminal coupled to the amplifier 530, the first capacitor 540, and adaptive to be coupled to the multi-class modulator circuitry 110. The first capacitor 540 has a first terminal coupled to the IDAC 505, the switching circuitry 515, the amplifier 530, and the third resistor 535. The first capacitor 540 has a second terminal coupled to the amplifier 530, the third resistor 535, and adaptive to be coupled to the multi-class modulator circuitry 110.

The fourth resistor 545 has a first terminal coupled to the IDAC 505, the switching circuitry 515, the amplifier 530, and the second capacitor 550. The fourth resistor 545 has a second terminal coupled to the amplifier 530, the second capacitor 550, and adaptive to be coupled to the multi-class modulator circuitry 110. The second capacitor 550 has a first terminal coupled to the IDAC 505, the switching circuitry 515, the amplifier 530, and the fourth resistor 545. The second capacitor 550 has a second terminal coupled to the amplifier 530, the fourth resistor 545, and adaptive to be coupled to the multi-class modulator circuitry 110.

The amplifier 530 receives the differential analog current from the IDAC 505. The resistors 535, 545 and the capacitors 540, 550 configure the amplifier 530 for closed loop operation. The amplifier 530 buffers the differential analog current to generate the differential input signal. In some examples, the amplifier 530 amplifies the differential analog current to generate the differential input signal. The resistors 535, 545 and the capacitors 540, 550 may filter relatively high frequency noise from the differential analog current. In some examples, the resistors 535, 545 and the capacitors 540, 550 limit current contributions of the differential analog current.

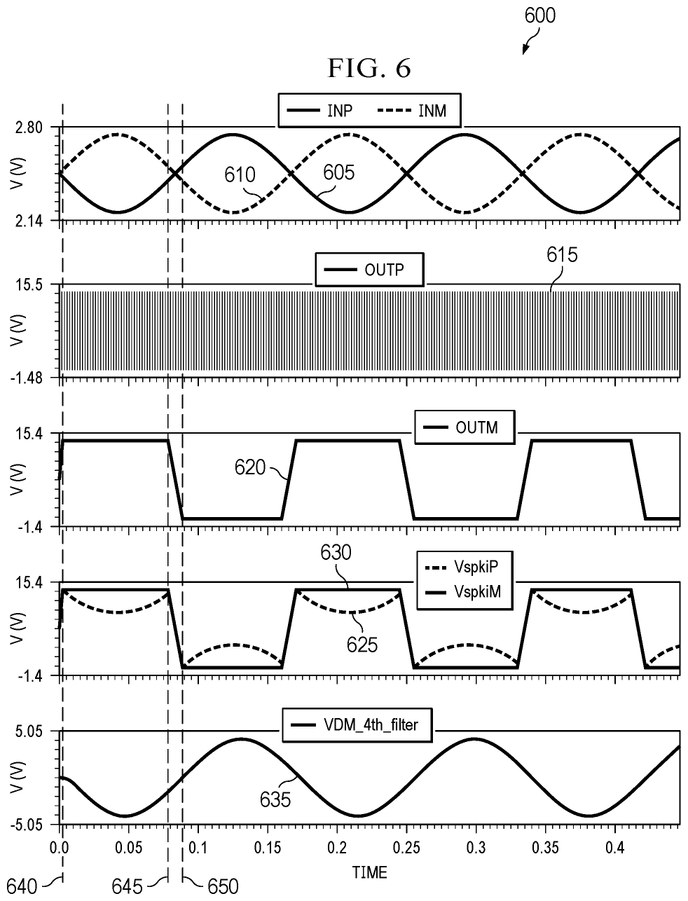

FIG. 6 is a timing diagram 600 of an example operation of the multi-class modulation circuitry 110 of FIGS. 1 and 2. In the example of FIG. 6, the timing diagram 600 illustrates an example plus input signal (INP) 605, an example minus input signal (INM) 610, an example plus output signal (OUTP) 615, an example minus output signal (OUTM) 620, an example filtered plus signal 625, an example filtered minus signal 630, and an example differential load signal 635. The timing diagram 600 illustrates example operations of the class D amplifier circuitry 130 of FIGS. 1, 2, and 3 and the class AB amplifier circuitry 140 of FIGS. 1, 2, and 4 to modulate the input signals 605, 610.

The plus input signal 605 is an illustration of a first one of the signals of the differential input signal from the audio source 105 of FIG. 1. In some described examples, the audio source 105 supplies the plus input signal 605 to the amplifier circuitries 130, 140. In such examples, the plus input signal 605 represents at least a portion of an audio signal to be supplied to the speaker 160 of FIG. 1 and/or the line out 170 of FIG. 1. The minus input signal 610 is an illustration of a second one of the signals of the differential input signal from the audio source 105. In some described examples, the audio source 105 supplies the minus input signal 610 to the amplifier circuitries 130, 140. In such examples, the minus input signal 610 represents at least a portion of an audio signal to be supplied to the speaker 160 and/or the line out 170.

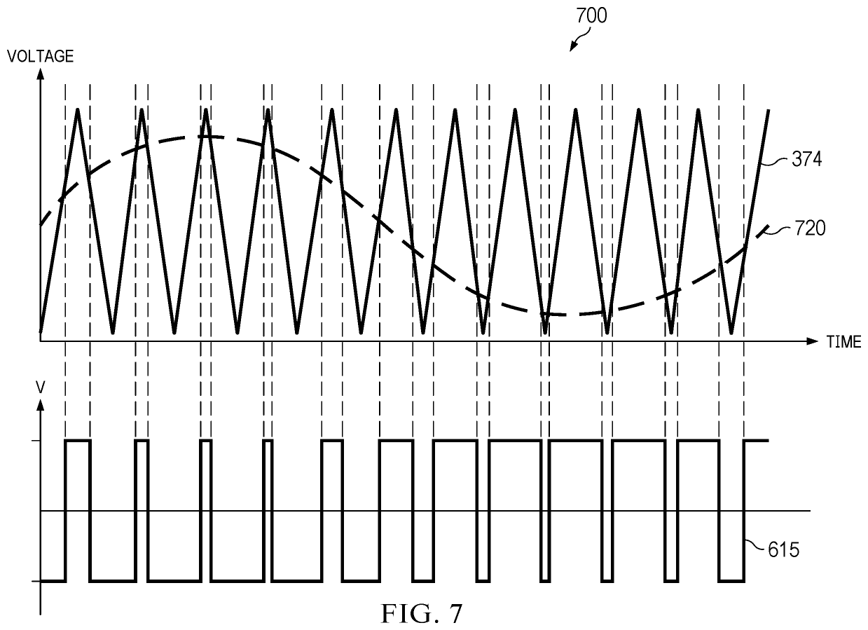

The plus output signal 615 is an illustration of a first one of the signals of the differential output signal from multi-class modulation circuitry 110. Specifically, the plus output signal 615 represents an output of the class D amplifier circuitry 130. In some described examples, the class D amplifier circuitry 130 supplies the plus output signal 615 to the filter circuitry 150 of FIGS. 1 and 2. In such examples, the plus output signal 615 represents at least a portion of a modulated audio signal to be supplied to the speaker 160 and/or the line out 170. In the example of FIG. 6, the plus output signal 615 has a switching frequency relatively higher than the frequency of the input signals 605, 610. However, for simplicity, another example of the plus output signal 615 is illustrated in FIG. 7, below.

The minus output signal 620 is an illustration of a second one of the signals of the differential output signal from multi-class modulation circuitry 110. Specifically, the minus output signal 620 represents an output of the class AB amplifier circuitry 140. In some described examples, the class AB amplifier circuitry 140 supplies the minus output signal 620 to the filter circuitry 150. In such examples, the minus output signal 620 represents at least a portion of a modulated audio signal to be supplied to the speaker 160 and/or the line out 170.

The filtered plus signal 625 is an illustration of a first one of the signals of the differential audio signal supplied to a load (e.g., the speaker 160, the line out 170) by the filter circuitry 150. Specifically, the filtered plus signal 625 represents the plus output signal 615 after being filtered by the filter circuitry 150. For example, the inductor 270 of FIG. 2 and/or the first capacitor 275 of FIG. 2 average the plus output signal 615 to generate the filtered plus signal 625. In such examples, variations in the duty cycle of the plus output signal 615 determine the amplitude of the filtered plus signal 625. An example modulation of a sinusoidal signal to generate the plus output signal 615 is illustrated in FIG. 7, below.

The filtered minus signal 630 is an illustration of a second one of the signals of the differential audio signal supplied to a load (e.g., the speaker 160, the line out 170) by the filter circuitry 150. Specifically, the filtered minus signal 630 represents the minus output signal 620 after being filtered by the filter circuitry 150. For example, the second capacitor 280 of FIG. 2 averages relatively high frequency frequencies (e.g., noise) of the minus output signal 620 to generate the filtered minus signal 630.

The differential load signal 635 is an illustration of the signal applied across a load by the filter circuitry 150. The differential load signal 635 is approximately equal to the differential between the filtered signals 625, 630. Advantageously, the differential load signal 635 is an amplified version of the input signals 605, 610. Advantageously, the modulation of the multi-class modulation circuitry 110 improves the total harmonic distortion (THD) of the differential load signal 635 across a wide range of frequencies and power levels.

At a first time 640, the minus output signal 620 leaves a linear region and enters a saturated region. When in the linear region, transistors of the second output stage circuitry 265 of FIGS. 2 and 4 are partially enabled, which decreases power efficiency. When in a saturated region, transistors of the second output stage circuitry 265 are fully enabled, which improves efficiency. In the described examples, the gain of the amplifier circuitry 260 of FIGS. 2 and 4 has a relatively high value to increase a duration of time the minus output signal 620 is in a saturated region, while decreasing the linear region.

At a second time 645, the minus output signal 620 leaves the saturated region of operation and enters a linear region of operation. At a third time 650, the minus output signal 620 leaves the linear region of operation and enters a saturated region of operation. However, between the times 645, 650, the minus output signal 620 linearly decreases.

Advantageously, the feedforward circuitry 230 of FIGS. 2 and 3B supplies the minus output signal 620 to the combination circuitry 225 of FIGS. 2 and 3B. Advantageously, the feedforward circuitry 230 combines minus output signal 620 and an error signal from the modulator circuitry 220 of FIGS. 2 and 3B to account for linear regions of operations. Advantageously, the comparison circuitry 235 of FIGS. 2 and 3A modulates the combined signal from the feedforward circuitry 230 to account for the linearities between the times 645, 650. Advantageously, the class D amplifier circuitry 130 adjusts the plus output signal 615 to compensate for the linearities of the class AB amplifier circuitry 140.

FIG. 7 is a timing diagram 700 of an example operation of the comparison circuitry 235 of FIGS. 2 and 3A. In the example of FIG. 7, the timing diagram 700 illustrates the triangular signal 375 of FIG. 3A, the plus output signal 615 of FIG. 6, and an example combined error signal 720. As described above, the triangular signal 375 is a triangular waveform having a frequency which determines the switching frequency of the plus output signal 615. Although in the example of FIG. 7 the triangular signal 375 has a first frequency, the triangular signal 375 may be modified to have a second frequency.

The combined error signal 720 is an illustration of an example output of the combination circuitry 225 of FIGS. 2 and 3B. In some described examples, the combined error signal 720 includes the error signal from the modulator circuitry 220 of FIGS. 2 and 3B and the minus output signal 620 of FIG. 6 from the feedforward circuitry 230 of FIGS. 2 and 3B. In some examples, the feedforward circuitry 230 amplifies the minus output signal 620 by a gain less than one to decrease the logic level of the minus output signal 620.

In the example of FIG. 3A, the sixth amplifier 374 of FIG. 3A compares the combined error signal 720 and the triangular signal 375. The sixth amplifier 374 generates a modulated signal responsive to the comparison. When supplied to the first output stage circuitry 240 of FIGS. 2 and 3A, the modulated signal becomes the plus output signal 615.

Advantageously, the comparison circuitry 235 compares the triangular signal 375 to the combined error signal 720 to generate a modulated signal of a varying duty cycle. The duty cycle of the plus output signal 615 represents the amplitude of the combined error signal 720 using a discrete waveform. Advantageously, the discrete waveform of the plus output signal 615 improves power efficiency responsive to decreasing linear operating conditions.

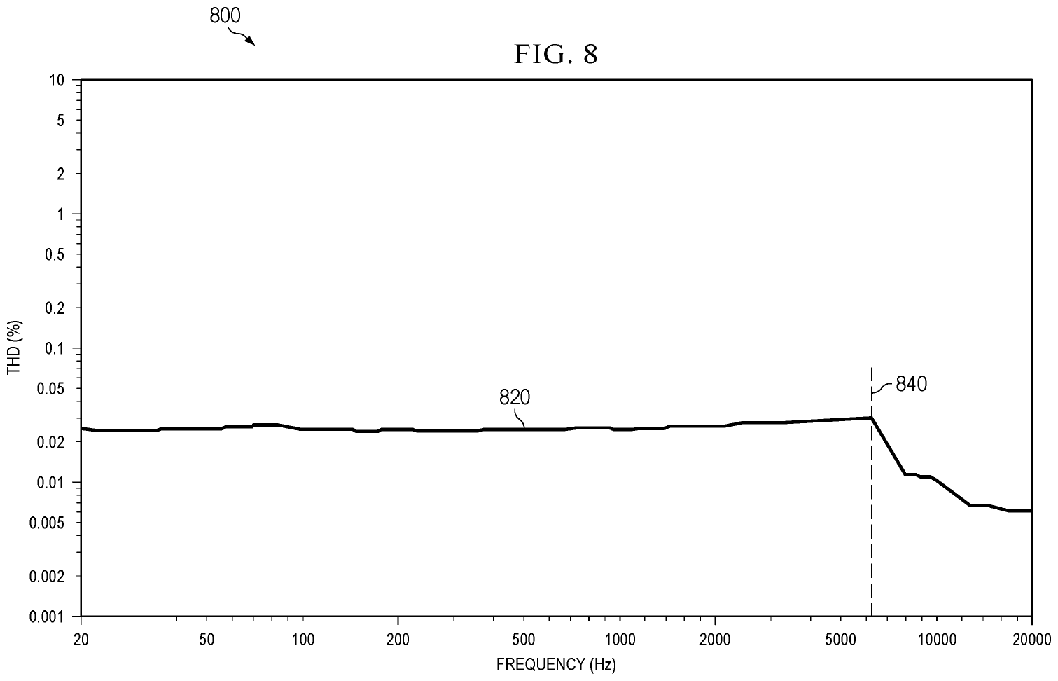

FIG. 8 is a plot 800 of an example operation of the multi-class modulation circuitry 110 of FIGS. 1 and 2 at a fixed output power. In the example of FIG. 8, the plot 800 illustrates an example total harmonic distortion (THD) 820 across a range of frequencies. The THD 820 is a performance characteristic of the output of the multi-class modulation circuitry 110. The THD 820 illustrates the dampening factor of the multi-class modulation circuitry 110. Before a first frequency 840, the THD 820 is approximately a fixed value. After the first frequency 840, the THD 820 decreases. Advantageously, the range of audible sounds is after the first frequency 840. Advantageously, the multi-class modulation circuitry 110 has a relatively low THD for applications that target frequencies of the audible noise range, such as the audio system 100 of FIG. 1.

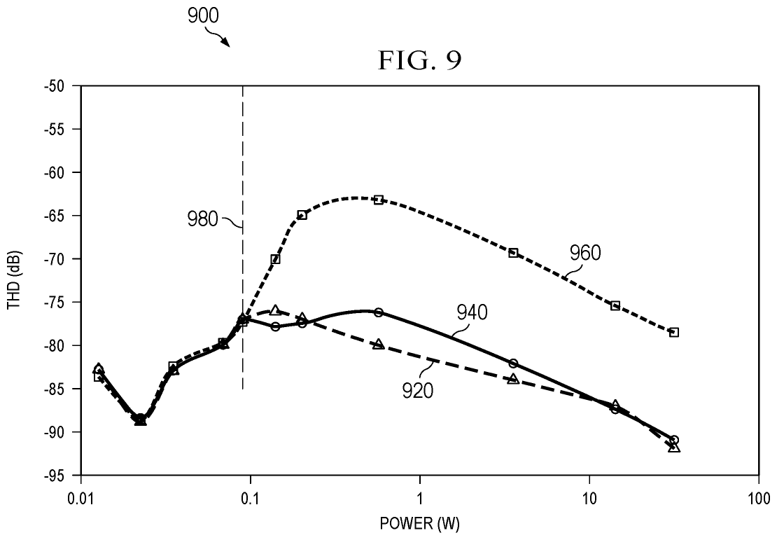

FIG. 9 is a plot 900 of an example operation of the multi-class modulation circuitry 110 of FIGS. 1 and 2 across a wide range of power levels. In the example of FIG. 9, the plot 900 includes a first example THD 920, a second example THD 940, and a third example THD 960. The THDs 920, 940, 960 illustrate operations of the multi-class modulation circuitry 110 for different variations of the resistors 120, 125 of FIGS. 1-4.

In the example of FIG. 9, the first THD 920 illustrates the THD characteristic of the multi-class modulation circuitry 110 when the resistors 120, 125 have exactly the same resistance. The second THD 940 illustrates the THD characteristic of the multi-class modulation circuitry 110 when the resistors 120, 125 have approximately a one-hundredth of a percent mismatch between resistances. The third THD 960 illustrates the THD characteristic of the multi-class modulation circuitry 110 when the resistors 120, 125 have approximately a five one-hundredths of a percent mismatch between resistances.

Below a power threshold 980, the THDs 920, 940, 960 are approximately the same. Advantageously, implementations of the multi-class modulation circuitry 110 supplies signals less than the power threshold 980 have higher tolerances for the resistors 120, 125. However, above the power threshold 980, mismatches between the resistors 120, 125 increase the THD of the multi-class modulation circuitry 110. Advantageously, reducing the mismatch between the resistors 120, 125 improves the THD of the multi-class modulation circuitry 110.

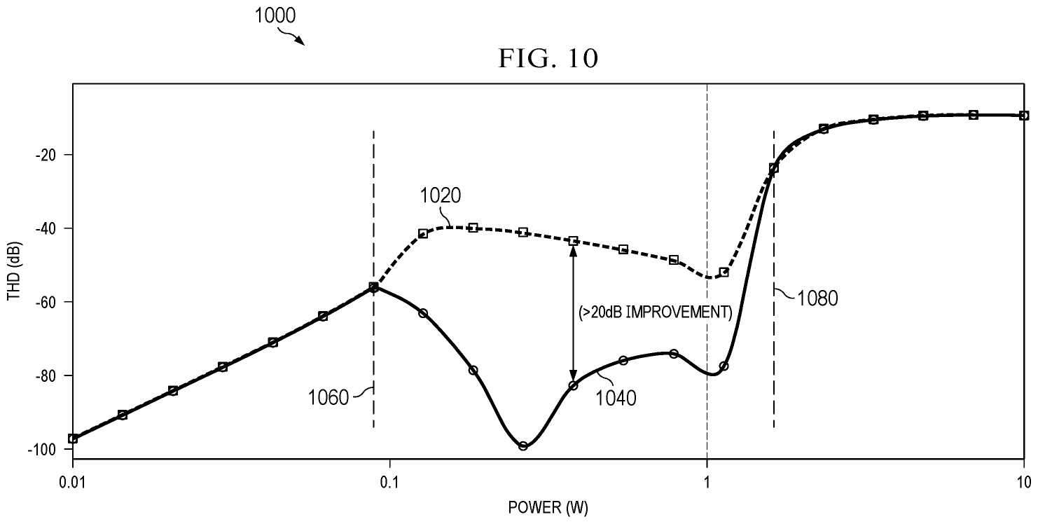

FIG. 10 is a plot 1000 of example operations of the multi-class modulation circuitry 110 of FIGS. 1 and 2 with and without the feedforward circuitry 230 of FIGS. 2 and 3B across a range of output power levels. In the example of FIG. 10, the plot 1000 includes a first example THD performance 1020 and a second example THD performance 1040. The first THD performance 1020 illustrates the THD of the multi-class modulation circuitry 110 without the feedforward circuitry 230. The second THD performance 1040 illustrates the THD of the multi-class modulation circuitry 110 with the feedforward circuitry 230.

Before a first power level 1060, the THD performances 1020, 1040 are approximately equal. After the first power level 1060 and before a second power level 1080, the second THD performance 1040 decreases responsive to the feedforward circuitry 230. After the second power level 1080, the THD performances 1020, 1040 are approximately equal. Advantageously, including the feedforward circuitry 230 improved the THD of the multi-class modulation circuitry 110.

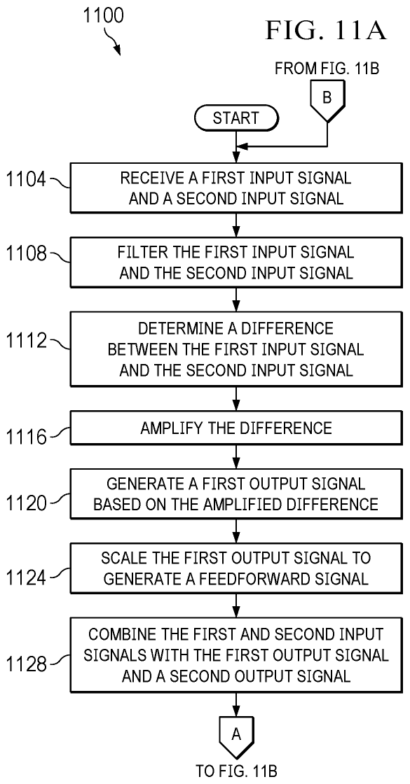

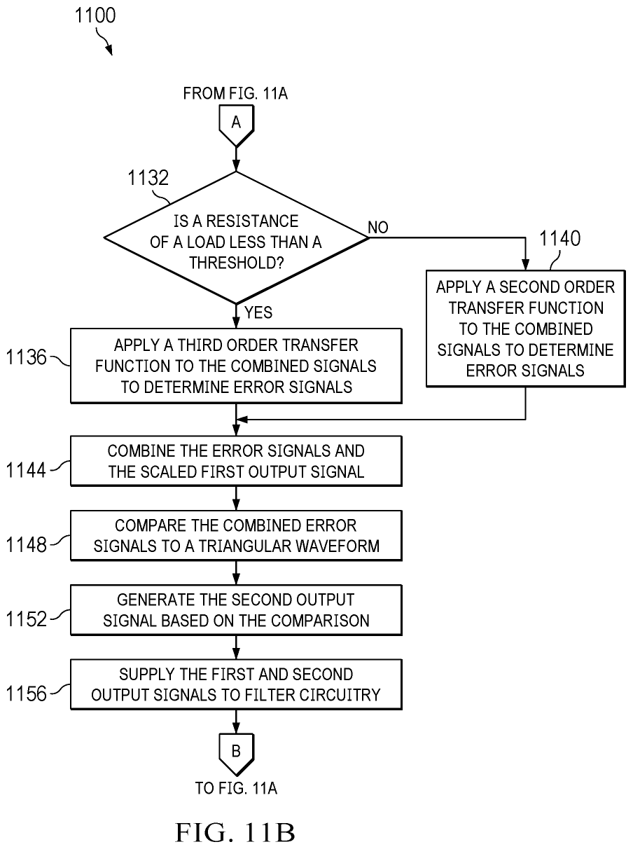

FIGS. 11A and 11B form a flowchart representative of example operations 1100 that may be performed to implement the multi-class modulation circuitry 110 of FIGS. 1 and 2. The example operations 1100 of FIG. 11 begin at block 1104, at which the multi-class modulation circuitry 110 of FIGS. 1 and 2 receive a first input signal and a second input signal. In some examples, the audio source 105 of FIG. 1 supplies a differential input signal having a plus input signal (INP) and a minus input signal (INM) to the multi-class modulation circuitry 110. In such examples, the conditioning circuitries 115, 135 of FIGS. 1-4 may receive the differential input signal.

The conditioning circuitries 115, 135 filter the first input signal and the second input signal. (Block 1108). In some examples, the conditioning circuitries 115, 135 are low pass filters. In such examples, the conditioning circuitries 115, 135 average relatively high frequency signals, such as noise. For example, the conditioning circuitries 115, 135 may filter frequencies that are not audible, such as frequencies greater than twenty kilohertz (kHz).

The amplifier circuitry 260 of FIG. 2 determines a difference between the first input signal and the second input signal. (Block 1112). In some examples, the amplifier circuitry 260 converts the differential input signal to a single ended signal. In such examples, the amplifier circuitry 260 determines the difference by subtracting the plus input signal from the minus input signal.

The amplifier circuitry 260 amplifies the difference. (Block 1116). In some examples, the amplifier circuitry 260 amplifies the single ended version of the differential input signal by a gain. In such examples, the gain of the amplifier circuitry 260 is a relatively high gain to saturate the output of the amplifier circuitry 260. For example, the amplifier circuitry 260 clips the output signal to supply values responsive to multiplying the single ended signal by a gain of eighty. In such an example, the output of the amplifier circuitry 260 operates in a linear mode of operation for a relatively small range of voltages near the common potential.

The second output stage circuitry 265 of FIGS. 2 and 4 generates a first output signal based on the amplified difference. (Block 1120). In some examples, the amplifier circuitry 260 supplies the mostly saturated output signal to the second output stage circuitry 265 to generate a minus output signal operating mostly in the saturation mode of operation. In such examples, the minus output signal has a relatively short duration of time in the linear region (e.g., between the times 645, 650 of FIG. 6). Advantageously, reducing the duration of time in the linear region of operation increases power efficiency.

The feedforward circuitry 230 of FIGS. 2 and 3B scales the first output signal to generate a feedforward signal. (Block 1124). In some examples, the feedforward circuitry 230 amplifies the minus output signal by a gain less than one to scale the minus output signal. In such examples, the gain of the feedforward circuitry 230 converts the power level of the minus output signal to a power level of the combination circuitry 225 of FIGS. 2 and 3B.

The first conditioning circuitry 115 combines the first and second input signal with the first output signal and a second output signal. (Block 1128). In some examples, components of the first conditioning circuitry 115 and/or the resistors 120, 125 of FIGS. 1-4 are summation resistors. In such examples, the first conditioning circuitry 115 and/or the resistors 120, 125 combine the differential pair of input signals and the differential pair of output signals from the resistors 120, 125.

The output detection circuitry 245 of FIGS. 2 and 3B determines if a resistance of a load is less than a threshold. (Block 1132). In some examples, the output detection circuitry 245 determines a resistance of the speaker 160 and/or the line out 170 by setting the plus output signal to a fixed voltage. In such examples, the output detection circuitry 245 determines the resistance based on the voltage of the minus output signal responsive to the fixed voltage of the plus output signal. The output detection circuitry 245 compares the determined resistance to a threshold resistance to determine whether the filter circuitry 150 is coupled to the speaker 160 or the line out 170.

If the output detection circuitry 245 determines that the resistance of the load is less than the threshold (e.g., Block 1132 returns a result of YES), the modulator circuitry 220 of FIGS. 2 and 3B applies a third order transfer function to the combined signals to determine error signals. (Block 1136). In some examples, the output detection circuitry 245 configures the modulator circuitry 220 to implement a third order transfer function. For example, the output detection circuitry 245 closes the switches 318, 320, 332, 334, 342, 346, 354, 356 of FIG. 3B and opens the switches 324, 326, 333, 335 of FIG. 3B, sets the resistances of the variable resistors 358, 363 of FIG. 3B to a first value, and the resistances of the variable resistors 415, 425 of FIG. 4 to first values. In such examples, the modulator circuitry 220 filters the combined signals from the first conditioning circuitry 115 and/or suppresses differences between the differential pair of input signals and the differential pair of output signals.

Turning to FIG. 11B, if the output detection circuitry 245 determines that the resistance of the load is greater than the threshold (e.g., Block 1132 returns a result of NO), the modulator circuitry 220 applies a second order transfer function to the combined signals to determine error signals. (Block 1140). In some examples, the output detection circuitry 245 configures the modulator circuitry 220 to implement a second order transfer function. For example, the output detection circuitry 245 opens the switches 318, 320, 332, 334, 342, 346, 354, 356 and closes the switches 324, 326, 333, 335, sets the resistances of the variable resistors 358, 363 to a second value, and the resistances of the variable resistors 415, 425 to second values. The second values to reduce a gain of the amplifier circuitry 260 of FIGS. 2 and 4. In such examples, the modulator circuitry 220 filters the combined signals from the first conditioning circuitry 115 and/or suppresses differences between the differential pair of input signals and the differential pair of output signals.

The feedforward circuitry 230 combines the error signals and the scaled first output signal. (Block 1144). In some examples, the feedforward circuitry 230 determines converts the error signals from the modulator circuitry 220 to a single ended error signal. Advantageously, the combined error signal from the feedforward circuitry 230 accounts for errors determined by the modulator circuitry 220 and the minus output signal.

The comparison circuitry 235 of FIGS. 2 and 3A compares the combined error signals to a triangular waveform. (Block 1148). In some examples, the comparison circuitry 235 generates a square waveform having a varying duty cycle by comparing the combined error signal to the triangular signal 375 of FIGS. 3A and 7. In such examples, the variation in the duty cycle of the square waveform represents the amplitude of the combined error signal during a cycle of the triangular signal 375.

The first output stage circuitry 240 of FIGS. 2 and 3A generates the second output signal based on the comparison. (Block 1152). In some examples, the first output stage circuitry 240 uses the square waveform from the comparison circuitry 235 to drive transistors of the power stage circuitry 379 of FIG. 3A. In such examples, switching of the power stage circuitry 379 generates the plus output signal 615 of FIGS. 6 and 7.

The amplifier circuitries 130, 140 supply the first and second output signal to filter circuitry. (Block 1156). In some examples, the output stage circuitries 240, 265 supply the output signals 615, 620 of FIG. 6 to the filter circuitry 150 of FIGS. 1 and 2. In such examples, the filter circuitry 150 supplies the output signals 615, 620 to one of the speaker 160 or the line out 170.

Although example methods are described with reference to the flowchart illustrated in FIGS. 11A and 11B, many other methods of implementing the multi-class modulation circuitry 110 may alternatively be used in accordance with this description. For example, the order of execution of the blocks may be changed, and/or some of the blocks described may be changed, eliminated, or combined. Similarly, additional operations may be included in the manufacturing process before, in between, or after the blocks shown in the illustrated examples.

In this description, the term “and/or” (when used in a form such as A, B and/or C) refers to any combination or subset of A, B, C, such as: (a) A alone; (b) B alone; (c) C alone; (d) A with B; (c) A with C; (f) B with C; and (g) A with B and with C. Also, as used herein, the phrase “at least one of A or B” (or “at least one of A and B”) refers to implementations including any of: (a) at least one A; (b) at least one B; and (c) at least one A and at least one B.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Numerical identifiers such as “first,” “second,” “third,” etc. are used merely to distinguish between elements of substantially the same type in terms of structure and/or function. These identifiers as used in the detailed description do not necessarily align with those used in the claims.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means+/−10 percent of the stated value, or, if the value is zero, a reasonable range of values around zero.

Modifications are possible in the described embodiments, and other embodiments are possible, within the scope of the claims.

What is claimed is:

1. An apparatus comprising:
class D amplifier circuitry having a first input, a second input, a third input, and an output, the first input of the class D amplifier circuitry coupled to the output of the class D amplifier circuitry; and
class AB amplifier circuitry having a first input, a second input, a third input, and an output, the first input of the class AB amplifier circuitry coupled to the first input of the class D amplifier circuitry and the output of the class D amplifier circuitry, the second and third inputs of the class AB amplifier circuitry coupled to the second and third inputs of the class D amplifier circuitry, and the output of the class AB amplifier circuitry.

2. The apparatus of claim 1, further comprising:
filter circuitry having a first terminal, a second terminal, a third terminal, and a fourth terminal, the first terminal of the filter circuitry coupled to the output of the class D amplifier circuitry, the first input of the class D amplifier circuitry, and the first input of the class AB amplifier circuitry, the second terminal of the filter circuitry coupled to the output of the class AB amplifier circuitry, the second input of the class D amplifier circuitry, the third input of the class D amplifier circuitry, the first input of the class AB amplifier circuitry, and the third input of the class AB amplifier circuitry; and
a speaker having a first terminal and a second terminal, the first terminal of the speaker coupled to the third terminal of the filter circuitry, the second terminal of the speaker coupled to the fourth terminal of the filter circuitry.

3. The apparatus of claim 1, wherein the class D amplifier circuitry comprising:
modulator circuitry having a first input, a second input, a first output, and a second output, the first input of the modulator circuitry coupled to the output of the class D amplifier circuitry and the first input of the class AB amplifier circuitry, the second input of the modulator circuitry coupled to the output of the class AB amplifier circuitry, the third input of the class D amplifier circuitry, the first input of the class AB amplifier circuitry, and the third input of the class AB amplifier circuitry; and
combination circuitry having a first input and a second input, the first input of the combination circuitry coupled to the first output of the modulator circuitry, the second input of the combination circuitry coupled to the second output of the modulator circuitry.

4. The apparatus of claim 3, wherein the combination circuitry further having an output, and the class D amplifier circuitry further comprising:
feedforward circuitry having a first input, a second input, and an output, the first input of the feedforward circuitry coupled to the output of the output of the combination circuitry, the second input of the feedforward circuitry coupled to the output of the class AB amplifier circuitry;
comparison circuitry having an input and an output, the input of the comparison circuitry coupled to the output of the feedforward circuitry; and
output stage circuitry having an input and an output, the input of the output stage circuitry coupled to the output of the comparison circuitry, the output of the output stage circuitry coupled to the first input of the class AB amplifier circuitry, and the first input of the modulator circuitry.

5. The apparatus of claim 1, further comprising an current digital-to-analog converter (IDAC) having a first terminal and a second terminal, the first terminal of the IDAC coupled to the first input of the class D amplifier circuitry, the output of the class D amplifier circuitry, and the first input of the class AB amplifier circuitry, the second terminal of the IDAC coupled to the second input of the class D amplifier circuitry, the third input of the class D amplifier circuitry, the second input of the class AB amplifier circuitry, the third input of the class AB amplifier circuitry, and the output of the class AB amplifier circuitry.

6. The apparatus of claim 1, wherein the class AB amplifier circuitry comprising:
amplifier circuitry having a first input, a second input, and an output, the first input of the amplifier circuitry coupled to first input of the class D amplifier circuitry and the output of the class D amplifier circuitry, the second input of the amplifier circuitry coupled to the second input of the class D amplifier circuitry, the third input of the class AB amplifier circuitry, and the output of the class AB amplifier circuitry; and
output stage circuitry having an input and an output, the input of the output stage circuitry coupled to the output of the amplifier circuitry, the output of the output stage circuitry coupled to the second input of the class D amplifier circuitry and the third input of the class D amplifier circuitry.

7. The apparatus of claim 6, wherein the input of the amplifier circuitry is a first input the class AB amplifier circuitry further comprising gain select circuitry having a first terminal and a second terminal, the first terminal of the gain select circuitry coupled to the second input of the class D amplifier circuitry, and the output of the output stage circuitry, the second terminal of the gain select circuitry coupled to the second input of the amplifier circuitry.

8. An apparatus comprising:
first amplifier circuitry having a first input, a second input, and an output; and
second amplifier circuitry including:
modulator circuitry having a first input, a second input, a first output, and a second output, the first input of the modulator circuitry coupled to the first input of the first amplifier circuitry and the output of the first amplifier circuitry, the second input of the modulator circuitry coupled to the second input of the first amplifier circuitry;
combination circuitry having a first input, a second input, and an output, the first input of the combination circuitry coupled to the first output of the modulator circuitry, the second input of the combination circuitry coupled to the second output of the modulator circuitry;
feedforward circuitry having a first input, a second input, and an output, the first input of the feedforward circuitry coupled to the output of the combination circuitry, the second input of the feedforward circuitry coupled to the output of the first amplifier circuitry;
comparison circuitry having an input and an output, the input of the comparison circuitry coupled to the output of the feedforward circuitry; and
output stage circuitry having an input and an output, the input of the output stage circuitry coupled to the output of the comparison circuitry, the output of the output stage circuitry coupled to the first input of first amplifier and the first input of the modulator circuitry.

9. The apparatus of claim 8, wherein the modulator circuitry comprising:
a first amplifier having a first input, a second input, a first output, and a second output, the first input of the first amplifier coupled to the first input of the first amplifier circuitry and the output of the first amplifier circuitry, the second input of the first amplifier coupled to the second input of the first amplifier circuitry and the output of the output stage circuitry;
a first resistor having a first terminal and a second terminal, the first terminal of the first resistor coupled to the first output of the first amplifier;
a second resistor having a first terminal and a second terminal, the first terminal of the second resistor coupled to the second output of the first amplifier; and
a second amplifier having a first input and a second input, the first input of the second amplifier coupled to the second terminal of the first resistor, the second input of the second amplifier coupled to the second terminal of the second resistor.

10. The apparatus of claim 9, wherein the modulator circuitry further comprising:
a first capacitor having a first terminal and a second terminal, the first terminal of the first capacitor coupled to the first input of the first amplifier circuitry, the output of the first amplifier circuitry, and the first input of the first amplifier, the second terminal of the first capacitor coupled to the first output of the first amplifier and the first terminal of the first resistor; and
a second capacitor having a first terminal and a second terminal, the first terminal of the second capacitor coupled to the second input of the first amplifier circuitry, the output of the output stage circuitry, and the second input of the first amplifier, the second terminal of the second capacitor coupled to the second output of the first amplifier and the first terminal of the second resistor.

11. The apparatus of claim 8, wherein the modulator circuitry further includes a third output, a fourth output, a fifth output, and a sixth output, the combination circuitry comprising:
a first resistor having a first terminal and a second terminal, the first terminal of the first resistor coupled to the first output of the modulator circuitry;
a second resistor having a first terminal and a second terminal, the first terminal of the second resistor coupled to the second output of the modulator circuitry; and
an amplifier having a first input, a second input, and an output, the first input of the amplifier coupled to the second terminal of the first resistor, the second input of the amplifier coupled to the second terminal of the second resistor, and the output of the amplifier coupled to the first input of the feedforward circuitry.

12. The apparatus of claim 8, wherein the input of the comparison circuitry is a first input of the comparison circuitry, the comparison circuitry further having a second input coupled to a triangular signal, the comparison circuitry configured to compare the output of the combination circuitry to the triangular signal.

13. The apparatus of claim 8, wherein the combination circuitry further has a third input, the apparatus further comprising third amplifier circuitry having an input and an output, the input of the third amplifier circuitry coupled to the first input of the first amplifier circuitry, the output of the first amplifier circuitry, and the first input of the modulator circuitry, the output of the third amplifier circuitry coupled to the third input of the combination circuitry.

14. The apparatus of claim 8, wherein the first amplifier circuitry is a class AB amplifier and the second amplifier circuitry is a class D amplifier.

15. An apparatus comprising:
first amplifier circuitry having a first input, a second input, and an output; and
second amplifier circuitry including:
third amplifier circuitry having a first input, a second input, and an output, the first input of the third amplifier circuitry coupled to the first input of the first amplifier circuitry and the output of the first amplifier circuitry, the second input of the third amplifier circuitry coupled to the second input of the first amplifier circuitry; and
output stage circuitry having an input and an output, the input of the output stage circuitry coupled to the output of the third amplifier circuitry, the output of the output stage circuitry coupled to the second input of the first amplifier circuitry.

16. The apparatus of claim 15, the second amplifier circuitry further comprising gain select circuitry having a first terminal and a second terminal, the first terminal of the gain select circuitry coupled to the second input of the first amplifier circuitry and the output of the output stage circuitry, the second terminal of the gain select circuitry coupled to a third input of the third amplifier circuitry.

17. The apparatus of claim 15, wherein the output of the third amplifier circuitry is a first output of the third amplifier circuitry, the output stage circuitry comprising:
level shifting circuitry having a first input, a second input, a first output and a second output, the first input coupled to the first output of the third amplifier circuitry, the second input coupled to the second output of the third amplifier circuitry; and
power stage circuitry having a first input, a second input, and an output, the first input of the power stage circuitry coupled to the first output of the level shifting circuitry, the second input of the power stage circuitry coupled to the second output of the power stage circuitry, the output of the power stage circuitry coupled to the second input of the first amplifier circuitry.

18. The apparatus of claim 17, wherein the level shifting circuitry comprising:
fourth amplifier circuitry having an input and an output, the input of the fourth amplifier circuitry coupled to the first output of the third amplifier circuitry, the output of the fourth amplifier circuitry coupled to the first input of the power stage circuitry, the fourth amplifier circuitry to shift a voltage of the first output of the third amplifier circuitry in reference to a supply voltage; and
fifth amplifier circuitry having an input and an output, the input of the fifth amplifier circuitry coupled to the second output of the third amplifier circuitry, the output of the fifth amplifier circuitry coupled to the second input of the power stage circuitry, the fifth amplifier circuitry to shift a voltage of the first output of the third amplifier circuitry in reference to a common potential.

19. The apparatus of claim 17, wherein the power stage circuitry comprising:
a first transistor having a first terminal and a control terminal, the control terminal of the first transistor coupled to the first output of the level shifting circuitry; and
a second transistor having a first terminal and a control terminal, the first terminal of the second transistor coupled to the first terminal of the first transistor and the second input of the first amplifier circuitry, the control terminal of the second transistor coupled to the second output of the level shifting circuitry.

20. The apparatus of claim 15, wherein the first amplifier circuitry is a class D amplifier circuitry and the second amplifier circuitry is a class AB amplifier circuitry.
